(19) United States
(12) Patent Application Publication
(10) Pub. No.: US 2026/0230054 A1
(43) Pub. Date: Aug. 6, 2026

(54) ACOUSTIC WAVE DEVICE

(71) Applicant: Murata Manufacturing Co., Ltd., Nagaokakyo-shi (JP)

(72) Inventors: Takuya YABU, Nagaokakyo-shi (JP); Kentaro NAKAMURA, Nagaokakyo-shi (JP)

(21) Appl. No.: 19/456,099

(22) Filed: Jan. 22, 2026

(30) Foreign Application Priority Data
Feb. 3, 2025 (JP) 2025-015933

(51) Int. Cl. H03H 9/13; H03H 9/17; H03H 9/54

(52) U.S. Cl. CPC H03H 9/133; H03H 9/171; H03H 9/54

(57) ABSTRACT

An acoustic wave device includes a piezoelectric substrate including a piezoelectric layer, an IDT electrode on the piezoelectric layer and including busbars and electrode fingers, and first and second reflectors positioned on the piezoelectric layer to be opposed to each other with the IDT electrode interposed therebetween and including reflector busbars and reflector electrode fingers. A direction of excitation of an acoustic wave at any portion of any electrode finger of the multiple electrode fingers is any of first to third directions. The first direction is perpendicular to a direction of extension of the electrode finger. The second direction is a direction in which a distance between the electrode finger and another electrode finger located adjacent to the electrode finger is shortest. The third direction is a direction of an electric field vector generated between the electrode finger and the other electrode finger adjacent to the electrode finger.

### CROSS REFERENCE TO RELATED APPLICATIONS

This application claims the benefit of priority to Japanese Patent Application No. 2025-015933 filed on Feb. 3, 2025. The entire contents of this application are hereby incorporated herein by reference.

### BACKGROUND OF THE INVENTION

### 1. Field of the Invention

The present invention relates to acoustic wave devices.

### 2. Description of the Related Art

Acoustic wave devices have heretofore been widely used in filters for mobile phones and the like. Japanese Unexamined Patent Application Publication No. 2012-005018 discloses an example of a surface acoustic wave device representing such an acoustic wave device. In this surface acoustic wave device, multiple comb-shaped electrode portions and a pair of reflectors are formed on a piezoelectric substrate. The pair of reflectors are formed on two sides in a traveling direction of a surface acoustic wave of the multiple comb-shaped electrode portions. The pair of reflectors are each weighted such that an intersecting width on the side not opposed to the comb-shaped electrode portion is narrower than an intersecting width on the side opposed to the comb-shaped electrode portion.

In the surface acoustic wave device described in Japanese Unexamined Patent Application Publication No. 2012-005018, each reflector is weighted by forming no electrodes at part of the piezoelectric substrate. Accordingly, there is a portion which does not function as the surface acoustic wave device at part of the piezoelectric substrate as a result of weighting the reflectors. Due to this, a region on the piezoelectric substrate cannot be fully and efficiently utilized.

### SUMMARY OF THE INVENTION

Example embodiments of the present invention provide acoustic wave devices that each efficiently utilize a region on a piezoelectric substrate.

An acoustic wave device according to an example embodiment of the present invention includes a piezoelectric substrate including a piezoelectric layer, an IDT electrode provided on the piezoelectric layer and including a pair of busbars and a plurality of electrode fingers, and a first reflector and a second reflector provided on the piezoelectric layer to be opposed to each other with the IDT electrode interposed therebetween, each reflector including a pair of reflector busbars and a plurality of reflector electrode fingers. Shapes in plan view of the plurality of electrode fingers of the IDT electrode are curved shapes. A direction of excitation of an acoustic wave at any portion of any electrode finger out of the plurality of electrode fingers is any of first to third directions. The first direction is a direction perpendicular to a direction of extension of the electrode finger. The second direction is a direction in which a distance between the electrode finger and another one of the electrode fingers located adjacent to the electrode finger is shortest. The third direction is a direction of an electric field vector generated between the electrode finger and the other one of the electrode fingers located adjacent to the electrode finger. In the first reflector, the pair of reflector busbars are a first reflector busbar and a second reflector busbar opposed to each other, and shapes in plan view of the plurality of reflector electrode fingers in each of the first reflector and the second reflector are curved shapes. The plurality of reflector electrode fingers in the first reflector include one or more first reflector electrode fingers including two end portions directly connected to the first reflector busbar and the second reflector busbar, and one or more second reflector electrode fingers including one end portion not directly connected to the first reflector busbar, the first reflector electrode fingers being located closer to an IDT electrode side than the second reflector electrode fingers. When viewed from a direction in which the first reflector busbar and the second reflector busbar are opposed to each other, all of the second reflector electrode fingers overlap at least one of the first reflector busbar and the second reflector busbar. In at least a partial region of the first reflector, a direction of propagation of the acoustic wave is a direction toward a second reflector busbar side, and a number of the reflector electrode fingers increases in the partial region toward the second reflector busbar side.

Acoustic wave devices according to example embodiments of the present invention allow a region on a piezoelectric substrate to be efficiently utilized.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along line I-I in FIG. 1.

FIG. 3 is a schematic enlarged plan view showing a portion near a first busbar and a second busbar of an IDT electrode in the first example embodiment of the present invention.

FIG. 4 is a schematic plan view of a first reflector in the first example embodiment of the present invention.

FIG. 5 is a schematic plan view of a second reflector in the first example embodiment of the present invention.

FIG. 6 is a schematic plan view showing a direction of excitation of an acoustic wave and directions of propagation of the acoustic wave in the first reflector and the second reflector in the first example embodiment of the present invention.

FIG. 7 is a schematic plan view of an acoustic wave device of a comparative example.

FIG. 8 is a diagram showing impedance frequency characteristics in the first example embodiment of the present invention and in the comparative example.

FIG. 9 is a diagram showing relationships between a frequency and a Q factor in the first example embodiment of the present invention and in the comparative example.

FIG. 10 is a schematic plan view showing circles which include arcs when shapes in plan view of electrode fingers of an IDT electrode in the first example embodiment of the present invention are approximated to the arcs.

FIG. 11 is a schematic enlarged plan view showing a portion near a first busbar and a second busbar of an IDT electrode in a modification of the first example embodiment of the present invention.

FIG. 12 is a schematic plan view of an acoustic wave device according to a second example embodiment of the present invention.

FIG. 13 is a diagram showing impedance frequency characteristics in the second example embodiment of the present invention and in a comparative example.

FIG. 14 is a diagram showing relationships between the frequency and the Q factor in the second example embodiment of the present invention and in the comparative example.

FIG. 15 is a schematic enlarged plan view showing a portion near a first busbar and a second busbar of an IDT electrode in a first modification of the second example embodiment of the present invention.

FIG. 16 is a schematic plan view of an acoustic wave device according to a second modification of the second example embodiment of the present invention.

FIG. 17A is a schematic cross-sectional view taken along a direction of extension of a first electrode finger in a third modification of the second example embodiment of the present invention, which shows a cross-section near a first edge region, a second edge region, and a central region of the electrode finger, and FIG. 17B is a schematic cross-sectional view taken along a direction of extension of a second electrode finger in the third modification of the second example embodiment of the present invention, which shows a cross-section near a first edge region, a second edge region, and a central region of the electrode finger.

FIG. 18 is a schematic plan view of an acoustic wave device according to a fourth modification of the second example embodiment of the present invention.

FIG. 19 is a schematic plan view of an acoustic wave device according to a fifth modification of the second example embodiment of the present invention.

FIG. 20 is a schematic plan view of an acoustic wave device according to a third example embodiment of the present invention.

FIG. 21 is a schematic plan view of an acoustic wave device according to a modification of the third example embodiment of the present invention.

FIG. 22 is a schematic plan view of an acoustic wave device according to a fourth example embodiment of the present invention.

FIG. 23 is a schematic plan view of an acoustic wave device according to a fifth example embodiment of the present invention.

FIG. 24 is a schematic elevational cross-sectional view of an acoustic wave device according to a sixth example embodiment of the present invention.

FIG. 25 is a schematic elevational cross-sectional view of an acoustic wave device according to a first modification of the sixth example embodiment of the present invention.

FIG. 26 is a schematic elevational cross-sectional view of an acoustic wave device according to a second modification of the sixth example embodiment of the present invention.

FIG. 27 is a schematic elevational cross-sectional view of an acoustic wave device according to a seventh example embodiment of the present invention.

FIG. 28 is a schematic elevational cross-sectional view of an acoustic wave device according to an eighth example embodiment of the present invention.

FIG. 29 is a schematic elevational cross-sectional view of an acoustic wave device according to a first modification of the eighth example embodiment of the present invention.

FIG. 30 is a schematic elevational cross-sectional view of an acoustic wave device according to a second modification of the eighth example embodiment of the present invention.

FIG. 31 is a schematic elevational cross-sectional view of an acoustic wave device according to a third modification of the eighth example embodiment of the present invention.

### DETAILED DESCRIPTION OF THE EXAMPLE EMBODIMENTS

The present invention will be clarified by describing specific example embodiments of the present invention below with reference to the drawings.

It is pointed out that the respective example embodiments described in the present specification are merely exemplary, and partial replacement or combination of configurations between different example embodiments is possible.

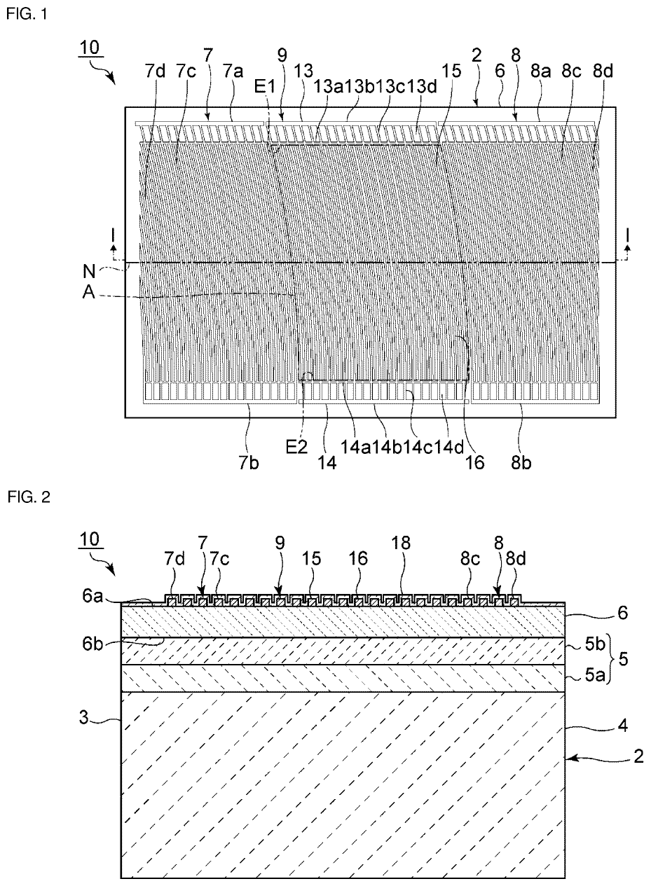

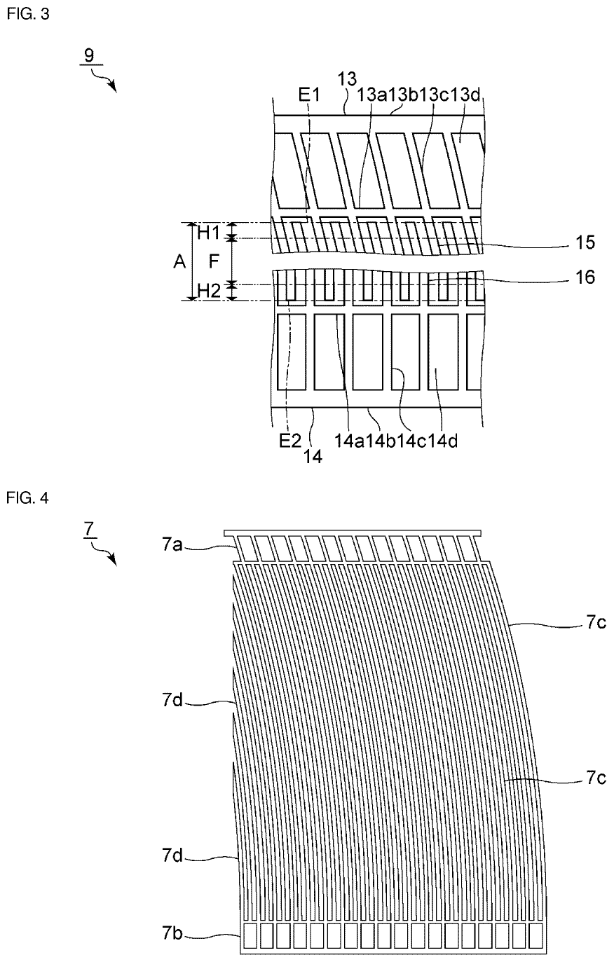

FIG. 1 is a schematic plan view of an acoustic wave device according to a first example embodiment of the present invention. FIG. 2 is a schematic cross-sectional view taken along line I-I in FIG. 1. Note that illustration of a dielectric film to be described later is omitted in FIG. 1.

As shown in FIG. 1, an acoustic wave device 10 includes a piezoelectric substrate 2. As shown in FIG. 2, the piezoelectric substrate 2 is a multilayer substrate that includes a piezoelectric layer 6. That is to say, the piezoelectric substrate 2 is a substrate having piezoelectricity. Specifically, the piezoelectric substrate 2 includes a support 3 and the piezoelectric layer 6. More specifically, the support 3 includes a support substrate 4 and an intermediate layer 5. The intermediate layer 5 includes a first layer 5a and a second layer 5b. The first layer 5a is provided on the support substrate 4. The second layer 5b is provided on the first layer 5a. The piezoelectric layer 6 is provided on the second layer 5b. Nonetheless, a layer structure of the piezoelectric substrate 2 is not limited to the above-mentioned structure. For example, the intermediate layer 5 may be a single-layered dielectric layer. Alternatively, the piezoelectric substrate 2 may be a substrate consisting of the piezoelectric layer 6, for example.

In the present example embodiment, silicon is used as a material of the support substrate 4. Silicon nitride is used as a material of the first layer 5a. Silicon oxide is used as a material of the second layer 5b. Rotated Y-cut X-propagating lithium tantalate is used as a material of the piezoelectric layer 6. As mentioned above, the piezoelectric layer 6 has a propagation axis. Moreover, a direction of extension of the propagation axis is an X direction. In the present example embodiment, the direction of extension of the propagation axis is parallel to a direction of extension of a two-dot chain line N in FIG. 1. Note that the materials of the respective layers of the piezoelectric substrate 2 are not limited to the above-mentioned materials.

The piezoelectric layer 6 includes a first principal surface 6a and a second principal surface 6b. The first principal surface 6a and the second principal surface 6b are opposed to each other. Of the first principal surface 6a and the second principal surface 6b, the second principal surface 6b is located on the support substrate 4 side. An IDT electrode 9 is provided to the first principal surface 6a of the piezoelectric layer 6.

A dielectric film 18 is provided on the piezoelectric layer 6 in such a way as to cover the IDT electrode 9. Specifically, the dielectric film 18 is provided to the first principal surface 6a of the piezoelectric layer 6. The IDT electrode 9 is hardly damaged because the IDT electrode 9 is protected by the dielectric film 18. In the present example embodiment, silicon oxide is used as a material of the dielectric film 18. Nonetheless, the material of the dielectric film 18 is not limited to the aforementioned material. Here, the dielectric film 18 does not necessarily have to be provided.

As shown in FIG. 1, the IDT electrode 9 includes a pair of busbars and multiple electrode fingers. Specifically, the pair of busbars are a first busbar 13 and a second busbar 14. The first busbar 13 and the second busbar 14 are opposed to each other. Specifically, the multiple electrode fingers are multiple first electrode fingers 15 and multiple second electrode fingers 16. One end portion of each of the first electrode fingers 15 is connected to the first busbar 13. One end portion of each of the second electrode fingers 16 is connected to the second busbar 14. The first electrode fingers 15 and the second electrode fingers 16 are interdigitated with one another.

Shapes in plan view of the first electrode fingers 15 and the second electrode fingers 16 are curved shapes. In the present specification, the plan view is a view from a direction corresponding to upside in FIG. 2. For example, of the support substrate 4 side and the piezoelectric layer 6 side in FIG. 2, the piezoelectric layer 6 side is the upside. Moreover, in the present specification, the plan view is assumed to be equivalent to a view from a principal surface opposing direction. The principal surface opposing direction is a direction in which the first principal surface 6a and the second principal surface 6b of the piezoelectric layer 6 are opposed to each other. More specifically, the principal surface opposing direction is a normal direction to the first principal surface 6a, for example.

FIG. 3 is a schematic enlarged plan view showing a portion near the first busbar and the second busbar of the IDT electrode in the first example embodiment.

Each of the first electrode fingers 15 and the second electrode fingers 16 includes a base end portion, a tip end portion, and a pair of edge portions. Specifically, the base end portion of the first electrode finger 15 is a portion connected to the first busbar 13. The pair of edge portions of the first electrode finger 15 are portions connecting the base end portion to the tip end portion. The tip end portion of the first electrode finger 15 is opposed to the second busbar 14 with a gap provided therebetween.

The base end portion of the second electrode finger 16 is a portion connected to the second busbar 14. The pair of edge portions of the second electrode finger 16 are portions connecting the base end portion to the tip end portion. The tip end portion of the second electrode finger 16 is opposed to the first busbar 13 with the gap provided therebetween.

Note that the first electrode fingers 15 and the second electrode fingers 16 may simply be referred to as the electrode fingers in the following description in some cases. The first busbar 13 and the second busbar 14 may simply be referred to as the busbars in some cases.

Referring back to FIG. 1, a first reflector 7 and a second reflector 8 are provided on the piezoelectric layer 6. The first reflector 7 and the second reflector 8 are opposed to each other in a direction of arrangement of the multiple electrode fingers of the IDT electrode 9 with the IDT electrode 9 interposed therebetween.

Each of the first reflector 7 and the second reflector 8 includes a pair of reflector busbars and multiple reflector electrode fingers. As with the multiple electrode fingers of the IDT electrode 9, shapes in plan view of the multiple reflector electrode fingers of the first reflector 7 and the second reflector 8 are curved shapes.

FIG. 4 is a schematic plan view of the first reflector in the first example embodiment.

The pair of reflector busbars in the first reflector 7 are a first reflector busbar 7a and a second reflector busbar 7b. The first reflector busbar 7a and the second reflector busbar 7b are opposed to each other. The multiple reflector electrode fingers in the first reflector 7 include multiple first reflector electrode fingers 7c and multiple second reflector electrode fingers 7d.

More specifically, one end portion of each of the first reflector electrode fingers 7c is connected to the first reflector busbar 7a. Another end portion of each of the first reflector electrode fingers 7c is connected to the second reflector busbar 7b.

One end portion of each of the second reflector electrode fingers 7d is not connected to any electrode. That is to say, in the present example embodiment, the one end portion of each of the second reflector electrode fingers 7d is connected neither to the first reflector busbar 7a nor to an electrode other than the first reflector busbar 7a. Here, the one end portion of each of the second reflector electrode fingers 7d only needs to be kept from being directly connected to the first reflector busbar 7a. For example, the one end portion of each of the second reflector electrode fingers 7d may be indirectly connected to the first reflector busbar 7a via another electrode.

Another end portion of each of the second reflector electrode fingers 7d is connected to the second reflector busbar 7b. Nonetheless, the other end portion of each of the second reflector electrode fingers 7d does not have to be directly connected to the second reflector busbar 7b. Alternatively, the two end portions of each of the second reflector electrode fingers 7d do not have to be directly connected to the first reflector busbar 7a and the second reflector busbar 7b. In this case, the two end portions of each of the second reflector electrode fingers 7d may be indirectly connected to the first reflector busbar 7a and the second reflector busbar 7b via other electrodes, for example.

The first reflector electrode fingers 7c are located closer to the IDT electrode 9 side shown in FIG. 1 than the second reflector electrode fingers 7d are. Thus, the first reflector electrode fingers 7c are the reflector electrode fingers which include the reflector electrode finger located on the side closest to the IDT electrode 9 and are arranged in order from the reflector electrode finger. Meanwhile, the second reflector electrode fingers 7d are the reflector electrode fingers which include the reflector electrode finger located on the side farthest from the IDT electrode 9 and are arranged in order from the reflector electrode finger. Nonetheless, the first reflector 7 only needs to include at least one first reflector electrode finger 7c and at least one second reflector electrode finger 7d.

When viewed from the direction in which the first reflector busbar 7a is opposed to the second reflector busbar 7b, all of the second reflector electrode fingers 7d overlap at least one of the first reflector busbar 7a and the second reflector busbar 7b.

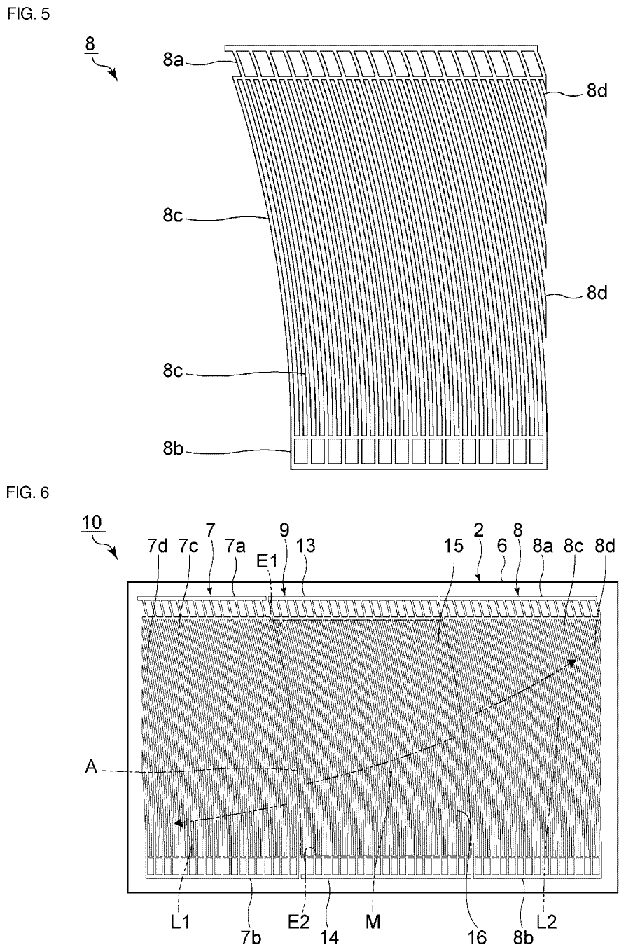

FIG. 5 is a schematic plan view of the second reflector in the first example embodiment.

The pair of reflector busbars in the second reflector 8 are a third reflector busbar 8a and a fourth reflector busbar 8b. The third reflector busbar 8a and the fourth reflector busbar 8b are opposed to each other. The multiple reflector electrode fingers in the second reflector 8 include multiple third reflector electrode fingers 8c and multiple fourth reflector electrode fingers 8d.

More specifically, one end portion of each of the third reflector electrode fingers 8c is connected to the third reflector busbar 8a. Another end portion of each of the third reflector electrode fingers 8c is connected to the fourth reflector busbar 8b. One end portion of each of the fourth reflector electrode fingers 8d is connected to the third reflector busbar 8a. Another end portion of each of the fourth reflector electrode fingers 8d is not connected to any electrode. That is to say, in the present example embodiment, the other end portion of each of the fourth reflector electrode fingers 8d is connected neither to the fourth reflector busbar 8b nor to an electrode other than the fourth reflector busbar 8b.

The third reflector electrode fingers 8c are located closer to the IDT electrode 9 side shown in FIG. 1 than the fourth reflector electrode fingers 8d are. Thus, the third reflector electrode fingers 8c are the reflector electrode fingers which include the reflector electrode finger located on the side closest to the IDT electrode 9 and are arranged in order from the reflector electrode finger. Meanwhile, the fourth reflector electrode fingers 8d are the reflector electrode fingers which include the reflector electrode finger located on the side farthest from the IDT electrode 9 and are arranged in order from the reflector electrode finger. Nonetheless, the second reflector 8 only needs to include at least one third reflector electrode finger 8c and at least one fourth reflector electrode finger 8d.

When viewed from the direction in which the third reflector busbar 8a is opposed to the fourth reflector busbar 8b, all of the fourth reflector electrode fingers 8d overlap at least one of the third reflector busbar 8a and the fourth reflector busbar 8b.

Referring back to FIG. 1, in the present example embodiment, energy of an acoustic wave can suitably be confined to the IDT electrode 9 side since the first reflector 7 and the second reflector 8 are configured as described above. Thus, a region on the piezoelectric substrate 2 can efficiently be utilized. Details of this feature will be described below. In the following description, the first reflector electrode fingers 7c, the second reflector electrode fingers 7d, the third reflector electrode fingers 8c, and the fourth reflector electrode fingers 8d may simply be referred to as the reflector electrode fingers in some cases. The first reflector busbar 7a, the second reflector busbar 7b, the third reflector busbar 8a, and the fourth reflector busbar 8b may simply be referred to as the reflector busbars in some cases.

The tip end portion of each of the first electrode fingers 15 and the second electrode fingers 16 includes a tip end. An imaginary line connecting the tip ends of the second electrode fingers 16 will be defined as a first envelope E1. An imaginary line connecting the tip ends of the first electrode fingers 15 will be defined as a second envelope E2.

A region located between the first envelope E1 and the second envelope E2 is an intersecting region A. More specifically, of the electrode fingers, a region surrounded by the edge portions of the electrode fingers on the one end portion side as well as the edge portions of the electrode fingers on the other end portion side in the direction of arrangement of the multiple electrode fingers, the first envelope E1, and the second envelope E2 is the intersecting region A. Accordingly, the first envelope E1 corresponds to an edge portion on the first busbar 13 side of the intersecting region A. The second envelope E2 corresponds to an edge portion on the second busbar 14 side of the intersecting region A. In the intersecting region A, every adjacent electrode fingers overlap each other when viewed from a direction of extension of the first envelope E1 or the second envelope E2.

In the present example embodiment, the direction of extension of the first envelope E1 is parallel to the direction of extension of the second envelope E2. Here, the direction of extension of the first envelope E1 and the direction of extension of the second envelope E2 may intersect with each other.

In the present example embodiment, the intersecting region A includes one curved region. The curved region is a region in which the shapes in plan view of the first electrode fingers 15 and the second electrode fingers 16 are curved shapes. One edge of the curved region of the intersecting region A is the first envelope E1. Another edge thereof is the second envelope E2.

An acoustic wave is excited in the intersecting region A by applying an alternating-current voltage to the IDT electrode 9. More specifically, an SH mode is excited as a main mode, for example. In this case, a Rayleigh wave becomes an unnecessary wave. Nonetheless, the main mode is not limited to the SH mode.

In the intersecting region A, a direction of excitation of the acoustic wave at any portion in any electrode finger out of the multiple electrode fingers is any of first to third directions mentioned below. The first direction is a direction perpendicular to a direction of extension of the electrode finger. The second direction is a direction in which a distance between the electrode finger and either the first electrode finger 15 or the second electrode finger 16 located adjacent to the electrode finger is shortest. The third direction is a direction of an electric field vector generated between the electrode finger and either the first electrode finger 15 or the second electrode finger 16 located adjacent to the electrode finger. To be more precise, the direction of the electric field vector herein is a direction of an electric field vector generated inside the piezoelectric layer 6. That is to say, the third direction is a direction of an electric field vector generated at a portion inside the piezoelectric layer 6 which overlaps a portion between the electrode finger and either the first electrode finger 15 or the second electrode finger 16 located adjacent to the electrode finger in plan view.

Here, since the shapes of the respective electrode fingers in the intersecting region A are the curved shapes, the direction of extension of an electrode finger varies depending on the position. In the present specification, the direction of extension of the electrode finger in the curved shape will be defined as described below unless otherwise stated.

First, the pair of edge portions of each electrode finger have curved shapes. In a case where an imaginary line parallel to the direction of extension of the propagation axis is drawn at any portion of the electrode finger in such a way as to link both of the edge portions, a gravity center at a portion located on the imaginary line will be defined as a representative point of the imaginary line. It is possible to draw innumerable imaginary lines on the electrode finger and innumerable representative points are present thereon. A direction of extension of a tangent to curved lines linking these representative points will be defined as the direction of extension of the electrode finger.

An angle between the direction of excitation of the acoustic wave and the direction of extension of the propagation axis of the piezoelectric layer 6 will be defined as an excitation angle θ_{C_prop}. In the present example embodiment, the shapes in plan view of the respective electrode fingers in the intersecting region A are the curved shapes. For this reason, the excitation angle θ_{C_prop} is non-uniform in the intersecting region A. Hence, the direction of excitation of the acoustic wave is non-uniform in the intersecting region A.

FIG. 6 is a schematic plan view showing the direction of excitation of the acoustic wave and the directions of propagation of the acoustic wave in the first reflector and the second reflector in the first example embodiment.

The angle between the direction of excitation of the acoustic wave and the direction of extension of the propagation axis of the piezoelectric layer 6 is defined as the excitation angle θ_{C_prop}. In the present example embodiment, a portion where the second envelope E2 passes is a portion where the excitation angle θ_{C_prop} is equal to 0°. The portions where the excitation angle θ_{C_prop} is equal to 0° are arranged linearly. On the other hand, in the present example embodiment, when portions where the excitation angles θ_{C_prop} are other than 0° and the excitation angles θ_{C_prop} are equal to one another are linked, such a line is curved as indicated with a curved line M. In other words, the line linking the portions where the directions of excitation of the acoustic wave are equal is the curved line M.

Nonetheless, the curved line M represents an example of the portions where the excitation angles θ_{C_prop} are other than 0° and the excitation angles θ_{C_prop} are equal. There are innumerable curved lines in the intersecting region A which are similar to the curved line M. As mentioned above, the shapes in plan view of the first electrode fingers 15 and the second electrode fingers 16 have shapes in which the portions where the excitation angles θ_{C_prop} are other than 0° and are equal to one another are arranged into the curved shapes.

Note that a positive direction of the excitation angle θ_{C_prop} will be defined as a counterclockwise direction in plan view in the present specification. In the present example embodiment, the excitation angle θ_{C_prop} is equal to or above 0° at any portion in the intersecting region A. Nonetheless, the intersecting region may include a portion where the excitation angle θ_{C_prop} is below 0° in the present invention.

The multiple reflector electrode fingers in the first reflector 7 and the second reflector 8 preferably have shapes corresponding to the multiple electrode fingers of the IDT electrode 9. Thus, the first reflector 7 and the second reflector 8 can effectively reflect the acoustic wave to the IDT electrode 9 side.

More specifically, in the first reflector 7 and the second reflector 8, the shapes of the multiple reflector electrode fingers are curved shapes such that the portions having the equal direction of propagation of the acoustic wave are arranged on trajectories that are continuous with a trajectory in the intersecting region A on which the portions having the equal direction of excitation of the acoustic wave are arranged.

For example, if the portions having the equal direction of propagation of the acoustic wave are arranged linearly in the first reflector 7, the acoustic wave propagates in the same direction through any reflector electrode fingers located adjacent to each other. For instance, the acoustic wave linearly propagates through any portion of any reflector electrode finger, and after propagating through that portion, reaches any portion of the adjacent reflector electrode finger. In this instance, the directions of propagation of the acoustic wave are equal between the portions of the two reflector electrode fingers on which the acoustic wave propagates. For this reason, the direction of propagation of the acoustic wave does not vary depending on the respective reflector electrode fingers on which the acoustic wave propagates. Hence, the direction of propagation of the acoustic wave is linear.

On the other hand, in the present example embodiment, the portions having the equal direction of propagation of the acoustic wave are arranged in a curved fashion. The direction in which the acoustic wave propagates on one reflector electrode finger is linear. For instance, the acoustic wave linearly propagates through any portion of any reflector electrode finger, and after propagating through that portion, reaches any portion of the adjacent reflector electrode finger. In this instance, the directions of propagation of the acoustic wave are different from each other between the portions of the two reflector electrode fingers on which the acoustic wave propagates. For this reason, the direction of propagation of the acoustic wave varies depending on the respective reflector electrode fingers on which the acoustic wave propagates. Hence, the acoustic wave propagates in a substantially curved fashion in the first reflector 7 as schematically indicated with an arrow L1 in FIG. 6.

In the present example embodiment, the direction of propagation of the acoustic wave is a direction toward the second reflector busbar 7b side in the entire region of the first reflector 7. Nonetheless, the direction of propagation of the acoustic wave only needs to be the direction toward the second reflector busbar 7b side in at least a partial region of the first reflector 7.

As schematically indicated with a curved arrow L2, the acoustic wave propagates in a substantially curved fashion in the second reflector 8 as well. In the present example embodiment, the direction of propagation of the acoustic wave is a direction toward the third reflector busbar 8a side in the entire region of the second reflector 8. Nonetheless, the direction of propagation of the acoustic wave only needs to be the direction toward the third reflector busbar 8a side in at least a partial region of the second reflector 8. Alternatively, in other example embodiments of the present invention, the second reflector 8 does not necessarily have to be configured as described above.

The present example embodiment preferably includes the following configurations: 1) that the multiple reflector electrode fingers in the first reflector 7 include the first reflector electrode fingers 7c and the second reflector electrode fingers 7d; 2) that all of the second reflector electrode fingers 7d overlap at least one of the first reflector busbar 7a and the second reflector busbar 7b when viewed from the direction in which the first reflector busbar 7a and the second reflector busbar 7b are opposed to each other; and 3) that the direction of propagation of the acoustic wave is the direction toward the second reflector busbar 7b side in at least the partial region of the first reflector 7, and the number of the reflector electrode fingers increases in the partial region toward the second reflector busbar 7b side.

Since the acoustic wave device 10 includes the above-mentioned configurations 1) to 3), it is possible to suitably confine energy of the acoustic wave on the IDT electrode 9 side, so that the region on the piezoelectric substrate 2 can efficiently be used. Moreover, it is easy to perform layout in a case of using the acoustic wave device 10 for a filter device.

Details of the aforementioned effects will be described by comparing the first example embodiment with a comparative example. In the following description, the direction in which the first reflector busbar 7a and the second reflector busbar 7b are opposed to each other may be referred to as a first reflector busbar opposing direction in some cases. The direction in which the third reflector busbar 8a and the fourth reflector busbar 8b are opposed to each other may be referred to as a second reflector busbar opposing direction in some cases. In the first example embodiment, the first reflector busbar opposing direction and the second reflector busbar opposing direction are directions orthogonal to the direction of extension of the propagation axis.

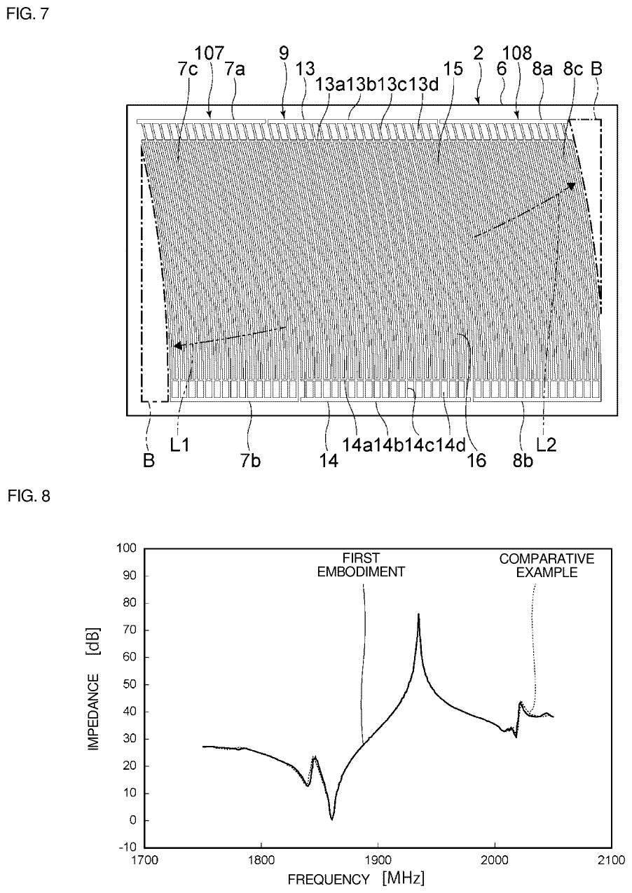

A comparative example shown in FIG. 7 is different from the first example embodiment in that a first reflector 107 does not include a second reflector electrode finger and that a second reflector 108 does not include a fourth reflector electrode finger. For this reason, all of the reflector electrode fingers of the first reflector 107 are the first reflector electrode fingers 7c. All of the first reflector electrode fingers 7c have one end portion directly connected to the first reflector busbar 7a. All of the first reflector electrode fingers 7c include another end portion directly connected to the second reflector busbar 7b. Moreover, the shapes in plan view of all of the first reflector electrode fingers 7c are curved shapes.

Accordingly, in the first reflector 107 of the comparative example, a blank region B is brought about at a portion overlapping the first reflector busbar 7a in the first reflector busbar opposing direction. Specifically, the blank region B is a region where no reflector electrode fingers are provided. Likewise, in the second reflector 108 of the comparative example, a blank region B is brought about at a portion overlapping the fourth reflector busbar 8b in the second reflector busbar opposing direction.

Impedance frequency characteristics and relationships between a frequency and a Q factor in the first example embodiment and the comparative example were derived by simulation.

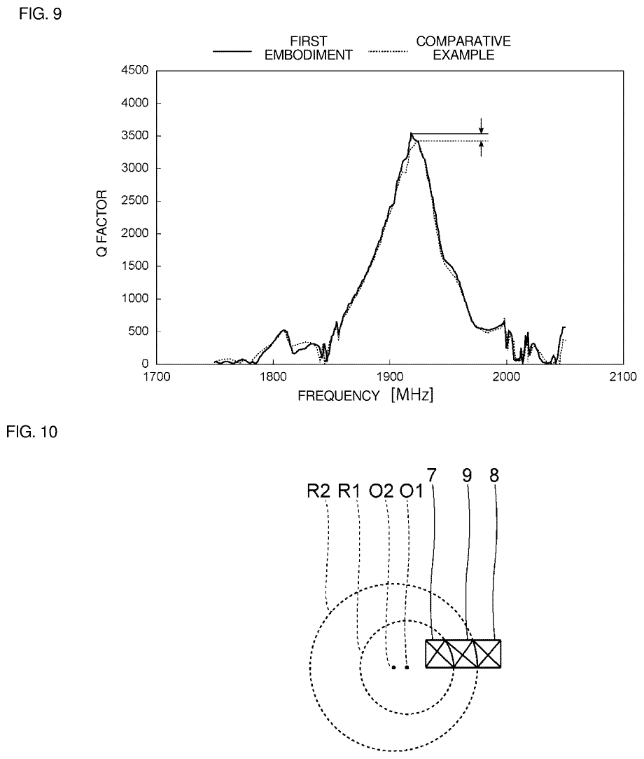

FIG. 8 is a diagram showing the impedance frequency characteristics in the first example embodiment and in the comparative example. FIG. 9 is a diagram showing relationships between the frequency and the Q factor in the first example embodiment and in the comparative example.

As shown in FIG. 8, the impedance frequency characteristics are not very different between the first example embodiment and the comparative example. Meanwhile, as shown in FIG. 9, a maximum value of the Q factor in the first example embodiment is greater than that in the comparative example. That is to say, the first example embodiment can suitably confine the energy of the acoustic wave to the IDT electrode 9 side due to the following reasons.

In the first reflector 7 of the first example embodiment shown in FIG. 6, the second reflector electrode fingers 7d are provided at the portion corresponding to the blank region B in the comparative example shown in FIG. 7. Thus, the number of the reflector electrode fingers increases toward the second reflector busbar 7b side. Moreover, in the entire region of the first reflector 7, the direction of propagation of the acoustic wave is the direction toward the second reflector busbar 7b side. Accordingly, the acoustic wave propagating from the IDT electrode 9 to the first reflector 7 can be reflected to the IDT electrode 9 side by using a larger number of reflector electrode fingers. Hence, the Q factor of the acoustic wave device 10 can be increased.

In addition, when viewed from the first reflector busbar opposing direction, all of the second reflector electrode fingers 7d overlap at least one of the first reflector busbar 7a and the second reflector busbar 7b. In this way, it is possible to reduce or prevent an increase in area of the first reflector 7 even when the second reflector electrode fingers 7d are provided. Hence, the acoustic wave can suitably be confined to the IDT electrode 9 side without increasing the size of the first reflector 7, and the Q factor of the acoustic wave device 10 can be increased. According to the above-described configuration, the region on the piezoelectric substrate 2 can efficiently be utilized.

As in the first example embodiment, the multiple reflector electrode fingers in the second reflector 8 preferably include the third reflector electrode fingers 8c and the fourth reflector electrode fingers 8d. In the second reflector 8 in this case, the fourth reflector electrode fingers 8d are provided in the region corresponding to the blank region B in the second reflector 108 of the comparative example shown in FIG. 7.

When viewed from the second reflector busbar opposing direction, all of the fourth reflector electrode fingers 8d preferably overlap at least one of the third reflector busbar 8a and the fourth reflector busbar 8b. In this way, it is possible to reduce or prevent an increase in area of the second reflector 8 even when the fourth reflector electrode fingers 8d are provided.

In at least a partial region of the second reflector 8, it is preferable that the direction of propagation of the acoustic wave be the direction toward the third reflector busbar 8a side, and that the number of the reflector electrode fingers increase in the region toward the third reflector busbar 8a side. Accordingly, the acoustic wave propagating from the IDT electrode 9 to the second reflector 8 can be reflected to the IDT electrode 9 side by using a larger number of reflector electrode fingers. Hence, the acoustic wave can suitably be confined to the IDT electrode 9 side without increasing the size of the second reflector 8, and the Q factor of the acoustic wave device 10 can be increased.

As described above, the configurations of the first reflector 7 and the second reflector 8 as in the first example embodiment make it possible to more efficiently utilize the region on the piezoelectric substrate 2.

Moreover, it is easy to perform layout when the acoustic wave device 10 is used in a filter device as an acoustic wave resonator. Specifically, the filter device includes multiple acoustic wave resonators that share the same piezoelectric substrate 2. Since an area of a portion on the piezoelectric substrate 2 where the acoustic wave device 10 is disposed can be reduced, it is possible to increase a degree of freedom in layout for disposing other acoustic wave resonators. In addition, in the first example embodiment, a shape in plan view of a portion where the first reflector 7, the IDT electrode 9, and the second reflector 8 are arranged is a shape close to a rectangle. Accordingly, it is even easier to perform layout for the filter device.

In the first reflector 7 of the first example embodiment, the first reflector electrode fingers 7c out of all of the reflector electrode fingers are the only reflector electrode fingers that are connected to the first reflector busbar 7a. Meanwhile, the first reflector electrode fingers 7c and the second reflector electrode fingers 7d out of all of the reflector electrode fingers are the reflector electrode fingers that are connected to the second reflector busbar 7b. That is to say, the number of the reflector electrode fingers connected to the second reflector busbar 7b is larger than the number of the reflector electrode fingers connected to the first reflector busbar 7a. Accordingly, a length of the second reflector busbar 7b is larger than a length of the first reflector busbar 7a.

More specifically, when viewed from the first reflector busbar opposing direction, an end portion of the second reflector busbar 7b on the side closer to the IDT electrode 9 does not overlap the first reflector busbar 7a. Here, when viewed from the first reflector busbar opposing direction, an end portion of the second reflector busbar 7b on the side farther from the IDT electrode 9 overlaps the first reflector busbar 7a.

In addition, when viewed from the first reflector busbar opposing direction, at least a portion of each second reflector electrode finger 7d overlaps both of the first reflector busbar 7a and the second reflector busbar 7b. In this way, it is possible to reduce the area of a region corresponding to the blank region B shown in FIG. 7. Accordingly, the region on the piezoelectric substrate 2 can be utilized more reliably and efficiently.

Furthermore, in the first reflector 7 of the first example embodiment, a line linking end portions of the second reflector electrode fingers 7d which are not directly connected to the second reflector busbar 7b is a straight line. An angle between a direction of extension of the straight line and a direction of extension of the first reflector busbar 7a is equal to or above about 45° and equal to or below about 135°, for example. This makes it possible to further reduce the area of the region corresponding to the blank region B shown in FIG. 7. Accordingly, the region on the piezoelectric substrate 2 can be utilized even more efficiently.

The same applies to the second reflector 8. Specifically, a length of the third reflector busbar 8a is larger than a length of the fourth reflector busbar 8b. More specifically, when viewed from the second reflector busbar opposing direction, an end portion of the third reflector busbar 8a on the side closer to the IDT electrode 9 does not overlap the fourth reflector busbar 8b. Here, when viewed from the second reflector busbar opposing direction, an end portion of the third reflector busbar 8a on the side farther from the IDT electrode 9 overlaps the fourth reflector busbar 8b.

In addition, when viewed from the second reflector busbar opposing direction, at least a portion of each fourth reflector electrode finger 8d overlaps both of the third reflector busbar 8a and the fourth reflector busbar 8b. In this way, it is possible to reduce the area of the region corresponding to the blank region B shown in FIG. 7. Accordingly, the region on the piezoelectric substrate 2 can be utilized more reliably and efficiently.

Furthermore, in the second reflector 8, a line linking end portions of the fourth reflector electrode fingers 8d which are not connected directly to the fourth reflector busbar 8b is a straight line. An angle between a direction of extension of the straight line and a direction of extension of the third reflector busbar 8 a is equal to or above about 45° and equal to or below about 135°, for example. This makes it possible to further reduce the area of the region corresponding to the blank region B shown in FIG. 7. Accordingly, the region on the piezoelectric substrate 2 can be utilized even more efficiently.

In the first example embodiment, the shapes in plan view of the multiple electrode fingers in the IDT electrode 9 are the curved shapes. Accordingly, in the intersecting region A in the first example embodiment, the direction of excitation of the acoustic wave and the excitation angle θ_{C_prop} thereof are non-uniform as described above. Specifically, in the intersecting region A, innumerable portions in the curved shapes having the excitation angles θ_{C_prop} other than 0° and the excitation angles θ_{C_prop} being equal are arranged in a direction in which the first busbar 13 and the second busbar 14 are opposed to each other. Moreover, the excitation angles θ_{C_prop} are different from one another among the portions in the curved shapes.

Propagation characteristics of an unnecessary wave are different at the portions having the excitation angles θ_{C_prop} different from one another. Accordingly, it is possible to disperse the unnecessary wave, thus effectively suppressing the unnecessary wave. In particular, an out-of-band unnecessary wave such as a Rayleigh wave can be suppressed in particular. In the present specification, “out-of-band” in the acoustic wave device means a lower frequency side relative to a resonant frequency and a higher frequency side relative to an anti-resonant frequency in the main mode.

In the first example embodiment, the resonant frequencies or the anti-resonant frequencies in the main mode of the acoustic wave device 10 substantially coincide with one another in the intersecting region A. Accordingly, it is possible to suppress the unnecessary wave effectively and to obtain good resonance characteristics more reliably.

To be more precise, at the portions in the intersecting region A where the excitation angles θ_{C_prop} are different from each other, relationships between the resonant frequencies and the anti-resonant frequencies are different from each other in the main mode and in the unnecessary wave. For this reason, in a case where the resonant frequencies or the anti-resonant frequencies in the main mode substantially coincide with one another at the respective portions in the intersecting region A, the resonant frequencies or the anti-resonant frequencies of the unnecessary wave are different from one another. Hence, the unnecessary wave is dispersed. Accordingly, it is possible to suppress the unnecessary wave.

In addition, the main mode is suitably excited since the resonant frequencies or the anti-resonant frequencies in the main mode substantially coincide with one another in the intersecting region A. Thus, it is possible to obtain good resonance characteristics more reliably.

In the present specification, a state where one frequency and another frequency substantially coincide with one another means a state where an absolute value of a difference between the two frequencies is equal to or below 2% relative to a reference frequency. The reference frequency represents a frequency in the case where the excitation angle θ_{C_prop} is equal to 0°.

In the intersecting region A, an absolute value of a difference between the highest resonant frequency and the lowest anti-resonant frequency in the main mode is preferably equal to or below about 1% relative to the reference frequency, for example. Alternatively, in the intersecting region A, an absolute value of a difference between the highest anti-resonant frequency and the lowest anti-resonant frequency in the main mode is preferably equal to or below about 1% relative to the reference frequency, for example. Thus, it is possible to obtain good resonance characteristics even more reliably.

The resonant frequencies or the anti-resonant frequencies in the main mode preferably substantially coincide with one another in at least a portion of the intersecting region A, or more preferably substantially coincide with one another in the entirety thereof. In this way, it is possible to disperse the unnecessary wave more reliably, thus suppressing the unnecessary wave more reliably. In addition, it is possible to obtain good resonance characteristics more reliably.

In the first example embodiment, since the shapes in plan view of the multiple electrode fingers in the IDT electrode 9 are the curved shapes, the innumerable portions in the curved shapes where the excitation angles θ_{C_prop} are other than 0° and the excitation angles θ_{C_prop} are equal to one another are arranged in the intersecting region A. Configurations of the multiple electrode fingers will be described below in more detail.

In the IDT electrode 9 shown in FIG. 1, the shapes in plan view of the first electrode fingers 15 and the second electrode fingers 16 are shapes each having a gentle change in curvature. Specifically, the shapes in plan view of the first electrode fingers 15 and the second electrode fingers 16 are shapes each of which can be approximated to an arc. Nonetheless, the shapes in plan view of the first electrode fingers 15 and the second electrode fingers 16 may be shapes each of which can be approximated to an elliptic arc, for example. Alternatively, the shapes in plan view of each of the electrode fingers may be a parabolic shape that cannot be approximated to an arc or an elliptic arc.

Concerning the multiple electrode fingers of the first example embodiment, an adjacent portion is defined as follows. Specifically, a portion including a portion located above the first envelope E1 of the first electrode finger 15 and being adjacent to a tip end portion of any of the second electrode fingers 16 is an adjacent portion of the first electrode finger 15. A portion including a portion located above the second envelope E2 of the second electrode finger 16 and being adjacent to a tip end portion of any of the first electrode fingers 15 is an adjacent portion of the second electrode finger 16.

Ranges of the tip end portion and the adjacent portion are based on λ representing a wavelength to be defined by an electrode finger pitch. The electrode finger pitch is a center-to-center distance between the first electrode finger 15 and the second electrode finger 16 located adjacent to each other. When the electrode finger pitch is denoted by p, λ=2p holds true. A portion in a range of about 1λ from a tip end of an electrode finger along a direction of extension of the electrode finger is assumed to be the tip end portion of the electrode finger. A range of the adjacent portion is also defined as a range of about 1λ along the direction of extension of the electrode finger.

The electrode finger pitch p that determines the wavelength λ may be defined as the narrowest electrode finger pitch at a portion where the excitation angle θ_{C_prop} is equal to 0°, for example. In the first example embodiment, the portion where the excitation angle θ_{C_prop} is equal to 0° is the portion on the second envelope E2.

The shapes in plan view of all of the electrode fingers in the IDT electrode 9 are preferably curved shapes that are different from one another. This example will be specifically represented by three types of examples. As the example of the first type, the curvatures are preferably different from each other between every two tip end portions, between every two adjacent portions, and every tip end portion and the corresponding adjacent portion in all of the first electrode fingers 15 and all of the second electrode fingers 16 which are located on the first envelope E1 side. More specifically, the curvatures are preferably different from each other between the tip end portions of every two second electrode fingers 16, between the adjacent portions of every two first electrode fingers 15, and between the tip end portion of every second electrode finger 16 and the adjacent portion of every first electrode finger 15 corresponding thereto.

As the example of the second type, the curvatures are preferably different from each other between every two tip end portions, between every two adjacent portions, and every tip end portion and the corresponding adjacent portion in all of the first electrode fingers 15 and all of the second electrode fingers 16 which are located on the second envelope E2 side. More specifically, the curvatures are preferably different from each other between the tip end portions of every two first electrode fingers 15, between the adjacent portions of every two second electrode fingers 16, and between the tip end portion of every first electrode finger 15 and the adjacent portion of every second electrode finger 16 corresponding thereto.

As the example of the third type, the curvatures are preferably different from each other between portions of all of the first electrode fingers 15 and all of the second electrode fingers 16, which are located at portions where the excitation angle θ_{C_prop} is equal to 0°. As described above, by forming the shapes in plan view of all of the electrode fingers in the IDT electrode 9 into the different curved shapes from one another, it is possible to suppress the unnecessary wave more reliably and effectively.

The first example embodiment satisfies all of the three types of examples described above. Nonetheless, the curvatures only need to be different from each other between two tip end portions, between two adjacent portions, or between a tip end portion and a corresponding adjacent portion, which are located on the first envelope E1 side, of at least one set of the electrode fingers out of the first electrode fingers 15 and the second electrode fingers 16.

In the first example embodiment, the intersecting region A includes one curved region. In the first example embodiment, the shapes in plan view of the multiple electrode fingers are shapes that can be approximated to arcs in the curved region. In other words, the shapes of the multiple electrode fingers are in the state of seeming to be approximated to the arcs in plan view. In addition, the shapes in plan view of the multiple electrode fingers are shapes having curves that are different from one another. Accordingly, the following relationships shown in FIG. 10 hold true.

FIG. 10 is a schematic plan view showing circles which include the arcs when shapes in plan view of the electrode fingers of the IDT electrode in the first example embodiment are approximated to the arcs. In FIG. 10, each of the IDT electrode 9, the first reflector 7, and the second reflector 8 is indicated with a schematic drawing that includes a figure representing its outline with addition of two diagonal lines thereto.

In FIG. 10, two circles of a circle R1 and a circle R2 are indicated with dashed lines. The circle R1 and the circle R2 are the circles including the respective arcs when the shapes in plan view of two electrode fingers different from each other are approximated to the arcs. A location of a center O1 of the circle R1 and a location of a center O2 of the circle R2 are different from each other.

In the curved region, locations of centers of circles including the arcs when the shapes in plan view of all of the first electrode fingers 15 and all of the second electrode fingers 16 are approximated to the arcs are preferably different from one another. In this case, the shapes in plan view of all of the electrode fingers in the IDT electrode 9 are the curved shapes that are different from one another as described above.

In the first example embodiment, the locations of the centers of the circles including the arcs when the shapes in plan view of all of the first electrode fingers 15 and all of the second electrode fingers 16 are approximated to the arcs are different from one another. Moreover, the respective reflector electrode fingers in the first reflector 7 and the second reflector 8 have the same shapes as the shapes of the respective electrode fingers of the IDT electrode 9. Specifically, in each of the first reflector 7 and the second reflector 8, locations of centers of circles including arcs when the shapes in plan view of all of the reflector electrode fingers in each of the first reflector 7 and the second reflector 8 are approximated to the arcs are different from one another.

As described above, the shapes of the multiple reflector electrode fingers in the first reflector 7 and the second reflector 8 have shapes corresponding to the multiple electrode fingers in the IDT electrode 9. Accordingly, the acoustic wave can effectively be reflected to the IDT electrode 9 side by using the first reflector 7 and the second reflector 8.

Nonetheless, in the curved region, the locations of the centers of the circles including the arcs only need to be different from each other in the case where the shapes in plan view of at least one set of the electrode fingers out of the first electrode fingers 15 and the second electrode fingers 16 in the IDT electrode 9 are approximated to the arcs. In each of the first reflector 7 and the second reflector 8, locations of centers of circles including arcs only need to be different from each other when shapes in plan view of at least one set of the reflector electrode fingers are approximated to the arcs.

Here, in the curved region, the shapes in plan view of the first electrode fingers 15 and the second electrode fingers 16 in the IDT electrode 9 may be capable of being approximated to elliptic arcs. In this case, in the curved region, locations of gravity centers of ellipses including the elliptic arcs are preferably different from one another when the shapes in plan view of all of the first electrode fingers 15 and all of the second electrode fingers 16 in the IDT electrode 9 are approximated to the elliptic arcs. The gravity center mentioned herein is a center of two focal points of the ellipse. Moreover, when shapes in plan view of all of the reflector electrode fingers in each of the first reflector 7 and the second reflector 8 are approximated to elliptic arcs, locations of gravity centers of ellipses including the elliptic arcs are preferably different from one another.

Nonetheless, in the curved region, the locations of the gravity centers of the ellipses including the elliptic arcs only need to be different from each other in the case where the shapes in plan view of at least one set of the electrode fingers out of the first electrode fingers 15 and the second electrode fingers 16 in the IDT electrode 9 are approximated to the elliptic arcs. In this case, in each of the first reflector 7 and the second reflector 8, locations of gravity centers of ellipses including elliptic arcs only need to be different from each other when shapes in plan view of at least one set of the reflector electrode fingers out of the multiple reflector electrode fingers are approximated to the elliptic arcs.

A line extending parallel to the direction of extension of the propagation axis is defined as a reference line. A degree of an angle between the reference line and the first envelope E1 is defined as an intersection angle θ_{C1_AP} while a degree of an angle between the reference line and the second envelope E2 is defined as an intersection angle θ_{C2_AP}. In the first example embodiment, both of the intersection angle θ_{C1_AP} and the intersection angle θ_{C2_AP} are equal to 0°. Nonetheless, the intersection angle θ_{C1_AP} and the intersection angle θ_{C2_AP} are not limited to 0°.

In the first example embodiment, a duty ratio varies according to the excitation angle θ_{C_prop} in the intersecting region A. Thus, the resonant frequencies are caused to substantially coincide with one another throughout the intersecting region A. Note that example embodiments of the present invention are not limited to this configuration.

For example, it is preferable that at least any of the duty ratio, the electrode finger pitch, and thicknesses of the first electrode fingers 15 and the second electrode fingers 16 vary according to the excitation angle θ_{C_prop}. It is preferable that at least any of these parameters vary according to the excitation angle θ_{C_prop} in at least a portion of the intersecting region A in such a way as to cause the resonant frequencies or the anti-resonant frequencies in the main mode to substantially coincide with one another. It is more preferable that at least any of these parameters vary according to the excitation angle θ_{C_prop} in the entire intersecting region A in such a way as to cause the resonant frequencies or the anti-resonant frequencies in the main mode to substantially coincide with one another. In these cases, it is possible to obtain good resonance characteristics in the acoustic wave device 10 more reliably.

Alternatively, in a case where a thickness of the intermediate layer 5 or the like in the piezoelectric substrate 2 affects the frequency, the aforementioned parameters may vary according to the excitation angle θ_{C_prop} in the intersecting region A. In the case where dielectric film 18 is provided on the piezoelectric substrate 2 in such a way as to cover the IDT electrode 9 as in the first example embodiment, a thickness of the dielectric film 18 may vary according to the excitation angle θ_{C_prop} in the intersecting region A. Multiple parameters out of the aforementioned parameters for the IDT electrode 9 or parameters not for the IDT electrode 9 may vary according to the excitation angle θ_{C_prop} in the intersecting region A. In these cases as well, it is possible to cause the resonant frequencies or the anti-resonant frequencies in the main mode to substantially coincide with one another in at least a portion of the intersecting region A or in the entirety thereof.

At least one of the electrode finger pitch and the duty ratio is preferably constant at the portions of the IDT electrode 9 where the excitation angles θ_{C_prop} are equal. It is more preferable that both of the electrode finger pitch and the duty ratio be constant at the portions of the IDT electrode 9 where the excitation angles θ_{C_prop} are equal. Thus, it is possible to obtain good resonance characteristics of the acoustic wave device 10 more reliably.

In the first example embodiment, the energy of the acoustic wave can effectively be confined to the intersecting region A side with the configuration of the pair of busbars in the IDT electrode 9. Details of this configuration will be described below.

As shown in FIG. 1, the first busbar 13 is provided with multiple apertures 13d. More specifically, the first busbar 13 includes a first inner busbar portion 13a, a first outer busbar portion 13b, and first connecting portions 13c. The first inner busbar portion 13a and the first outer busbar portion 13b are opposed to each other. Of the first inner busbar portion 13a and the first outer busbar portion 13b, the first inner busbar portion 13a is located on the intersecting region A side. The first connecting portions 13c connect the first inner busbar portion 13a to the first outer busbar portion 13b. Each of the aforementioned apertures 13d is an aperture surrounded by the first inner busbar portion 13a, the first outer busbar portion 13b, and the first connecting portions 13c.

Likewise, the second busbar 14 also includes a second inner busbar portion 14a, a second outer busbar portion 14b, and second connecting portions 14c. The second busbar 14 is provided with apertures 14d.

The first inner busbar portion 13a extends parallel to the first envelope E1. As shown in FIG. 3, the first inner busbar portion 13a is opposed to the second electrode fingers 16 with a gap provided therebetween. The second inner busbar portion 14a extends parallel to the second envelope E2. The second inner busbar portion 14a is opposed to the first electrode fingers 15 with a gap provided therebetween.

In the present example embodiment, each of the first connecting portions 13c of the first busbar 13 extends on an extension of a first electrode finger 15. The first connecting portions 13c are not provided on extensions of the second electrode fingers 16. On the other hand, in the intersecting region A, the first electrode fingers 15 and the second electrode fingers 16 are alternately arranged. For this reason, an acoustic velocity in a region of the first busbar 13 provided with the apertures 13d is higher than an acoustic velocity in the intersecting region A. Accordingly, a high acoustic velocity region is provided in the region of the first busbar 13 where the apertures 13d are located. Here, the high acoustic velocity region is a region in which the acoustic velocity is higher than an acoustic velocity in a region located on a central side in the intersecting region A.

To be more precise, as shown in FIG. 3, the intersecting region A includes a central region F and a pair of edge regions. Specifically, the pair of edge regions are a first edge region H1 and a second edge region H2. The first edge region H1 includes the first envelope E1 as an edge portion. The second edge region H2 includes the second envelope E2 as an edge portion. The first edge region H1 and the second edge region H2 are opposed to each other with the central region F interposed therebetween. The aforementioned high acoustic velocity region is the region in which the acoustic velocity is higher than the acoustic velocity in the central region F.

Here, the first edge region H1 is assumed to be a region in which the tip end portions of the second electrode fingers 16 and the adjacent portions of the first electrode fingers 15 are located. That is to say, based on the second electrode fingers 16, the first edge region H1 is assumed to be a region in a range of about 1λ from the tip ends of the second electrode fingers 16 along a direction of extension of the second electrode fingers 16. Likewise, based on the first electrode fingers 15, the second edge region H2 is assumed to be a region in a range of about 1λ from the tip ends of the first electrode fingers 15 along a direction of extension of the first electrode fingers 15.

As with the region of the first busbar 13 provided with the apertures 13d, a high acoustic velocity region is also provided in the region of the second busbar 14 where the apertures 14d are provided.

Here, a leakage of the energy of the acoustic wave may occur along with mode conversion of the main mode. In a case where an SH wave is used as the main mode of the acoustic wave, for example, the energy of the acoustic wave leaks out by conversion from the SH wave to a Rayleigh wave or from the SH wave to a bulk wave. Such a leakage occurs from the intersecting region A side to the busbar side.

In the first example embodiment, the first inner busbar portion 13a is opposed to the second electrode fingers 16 with the gap provided therebetween. Accordingly, it is possible to reduce or prevent of the energy of the acoustic wave along with the mode conversion. Moreover, the second inner busbar portion 14a is opposed to the first electrode fingers 15 with the gap provided therebetween. Accordingly, it is possible to reduce or prevent of the energy of the acoustic wave along with the mode conversion.

A distance between the first inner busbar portion 13a and each second electrode finger 16 is preferably equal to or below about 0.5λ, for example. Likewise, a distance between the second inner busbar portion 14a and each first electrode finger 15 is preferably equal to or below about 0.5λ, for example. Thus, it is possible to effectively reduce or prevent of the energy of the acoustic wave along with the mode conversion.

In addition, the high acoustic velocity region is between the first inner busbar portion 13a and the first outer busbar portion 13b. Accordingly, the energy of the acoustic wave can effectively be confined to the intersecting region A side. Likewise, the high acoustic velocity region is between the second inner busbar portion 14a and the second outer busbar portion 14b. Accordingly, the energy of the acoustic wave can effectively be confined to the intersecting region A side.

As shown in FIG. 1, each of the first reflector busbar 7a of the first reflector 7 and the third reflector busbar 8a of the second reflector 8 is provided with multiple apertures as with the first busbar 13. Each of the second reflector busbar 7b of the first reflector 7 and the fourth reflector busbar 8b of the second reflector 8 is provided with multiple apertures as with the second busbar 14. Nonetheless, each of the reflector busbars of the respective reflectors does not necessarily have to be provided with apertures.

In the meantime, in the IDT electrode 9 of the first example embodiment, the shapes in plan view of the multiple electrode fingers are shapes which can be approximated to arcs. Here, the shapes in plan view of the multiple electrode fingers may include arc shapes, for example. In this case, the shapes in plan view of the multiple electrode fingers include shapes corresponding to respective arcs in multiple concentric circles. Accordingly, centers of the circles including the arcs in the shapes of the respective electrode fingers coincide with one another. This center will be defined as a fixed point.

As described above, in the first example embodiment, the portions where the excitation angles θ_{C_prop} are equal are arranged in the curved shape. On the other hand, in the case where the shapes in plan view of the multiple electrode fingers are the arc shapes, the portions where the excitation angles θ_{C_prop} are equal are arranged linearly. Specifically, the portions where the excitation angles θ_{C_prop} are equal are arranged on a straight line that passes through the aforementioned fixed point and the intersecting region.

Alternatively, the shapes in plan view of the multiple electrode fingers may include elliptic arc shapes, for example. In this case, the shapes in plan view of the multiple electrode fingers include shapes corresponding to respective elliptic arcs in multiple ellipses having the gravity centers at the same position. When the gravity center is defined as a fixed point, the portions where the excitation angles θ_{C_prop} are equal are arranged on a straight line that passes the fixed point and the intersecting region.

The shapes of the multiple reflector electrode fingers of the first reflector and the second reflector are preferably the shapes corresponding to the multiple electrode fingers of the IDT electrode. Specifically, in the case where the shapes in plan view of the multiple electrode fingers include the arc shapes, it is preferable that the shapes in plan view of the multiple reflector electrode fingers also have the arc shapes. The centers of the circles including the arcs in the shapes of the multiple electrode fingers and of the multiple reflector electrode fingers preferably coincide with one another. In the case where the shapes in plan view of the multiple electrode fingers include the elliptic arc shapes, it is preferable that the shapes in plan view of the multiple reflector electrode fingers also have the elliptic arc shapes. The gravity centers of the ellipses including the elliptic arcs in the shapes of the multiple electrode fingers and of the multiple reflector electrode fingers preferably coincide with one another. Accordingly, the acoustic wave can effectively be reflected to the IDT electrode side by using the first reflector and the second reflector.

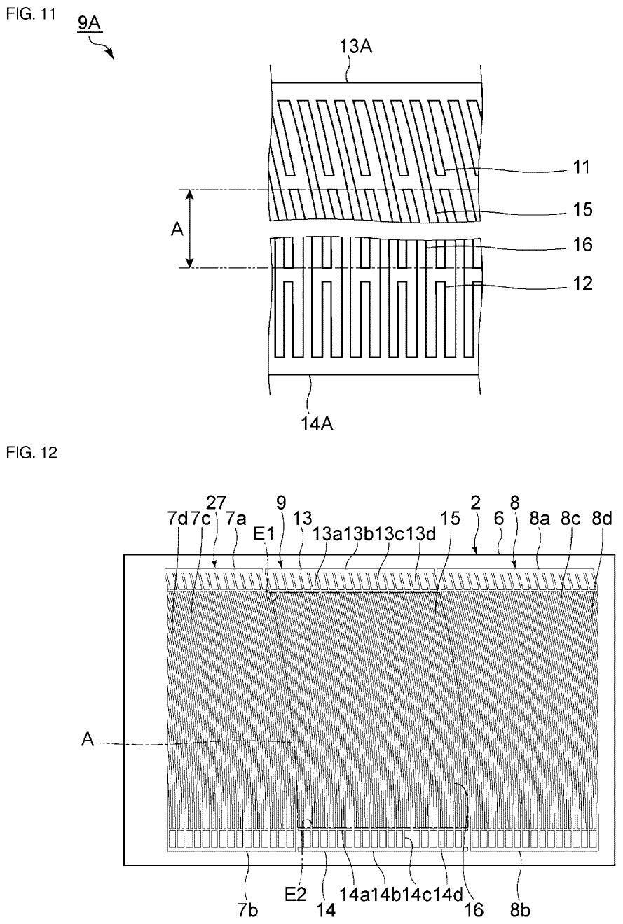

As shown in FIG. 1, each of the busbars of the IDT electrode 9 is provided with the multiple apertures. Nonetheless, each busbar of the IDT electrode 9 does not necessarily have to be provided with apertures. In addition, each busbar may be provided with multiple offset electrodes. For example, in a modification of the first example embodiment shown in FIG. 11, an IDT electrode 9A includes multiple offset electrodes. Specifically, the multiple offset electrodes of the IDT electrode 9A are multiple first offset electrodes 11 and multiple second offset electrodes 12. One end portion of each of the first offset electrodes 11 is connected to a first busbar 13A. The first electrode fingers 15 and the first offset electrodes 11 are alternately arranged. Note that the first busbar 13A is not provided with apertures.

One end portion of each of the second offset electrodes 12 is connected to a second busbar 14A. The second electrode fingers 16 and the second offset electrodes 12 are alternately arranged. The second busbar 14A is not provided with apertures.

As with the first electrode fingers 15 and the second electrode fingers 16, each of the first offset electrodes 11 and the second offset electrodes 12 includes a base end portion and a tip end portion. The base end portions of the first electrode fingers 15 and of the first offset electrodes 11 are portions connected to the first busbar 13A. The base end portions of the second electrode fingers 16 and of the second offset electrodes 12 are portions connected to the second busbar 14A. The tip end portions of the first electrode fingers 15 and the tip end portions of the second offset electrodes 12 are opposed to one another with a gap provided therebetween. The tip end portions of the second electrode fingers 16 and the tip end portions of the first offset electrodes 11 are opposed to one another with a gap provided therebetween.

In the present modification, shapes in plan view of the first offset electrodes 11 are curved shapes. Specifically, the shape of each first offset electrode 11 is a shape corresponding to the shape of the second electrode finger 16 opposed thereto. More specifically, the shapes in plan view of the first offset electrodes 11 are shapes that can be approximated to arcs. Moreover, circles including respective arcs when shapes in plan view of any first offset electrode 11 and the second electrode finger 16 opposed to the first offset electrode 11 are approximated to the arcs are the same circle.

Curvatures at the tip end portions of all of the first offset electrodes 11 are different from one another. Thus, conditions of the intersecting region A in which the main mode is excited and conditions of the region where the first offset electrodes 11 are provided can at least be brought close to each other or match each other. In this way, the main mode can effectively be reflected to the intersecting region A side. Nonetheless, the curvatures at the tip end portions of at least one set of the first offset electrodes 11 out of the multiple first offset electrodes 11 may be different from each other, for example. The main mode can effectively be reflected to the intersecting region A side in this case as well.

In the case where the shapes in plan view of the multiple electrode fingers can be approximated to the elliptic arcs in the intersecting region A as well, it is preferable that the shapes in plan view of the first offset electrodes 11 be the curved shapes and that the curvatures of the respective first offset electrodes 11 be not constant. The shapes in plan view of the first offset electrodes 11 are preferably the shapes that can be approximated to the elliptic arcs. Moreover, ellipses including respective elliptic arcs when shapes in plan view of any first offset electrode 11 and the second electrode finger 16 opposed to the first offset electrode 11 are approximated to the elliptic arcs are preferably the same ellipse.

It is preferable that the curvatures of the tip end portions of at least one set of the first offset electrodes 11 out of the multiple first offset electrodes 11 be different from each other, and it is more preferable that the curvatures of the tip end portions of all of the first offset electrodes 11 be different from one another. Thus, the main mode can effectively be reflected to the intersecting region A side.

Alternatively, the shapes in plan view of the first offset electrodes 11 may be linear shapes. In this case, it is possible to reduce distances from the tip end portions of the first offset electrodes 11 to the first busbar 13A. Thus, electric resistance of the IDT electrode 9A can be reduced. Accordingly, it is possible to reduce or prevent an increase in insertion loss in the case of using the acoustic wave device for the filter device.

In the present modification, the shapes in plan view of the second offset electrodes 12 are straight shapes. The shapes of the respective second offset electrodes 12 are therefore the shapes corresponding to the shapes of the first electrode fingers 15 opposed thereto. Accordingly, the main mode can effectively be reflected to the intersecting region A side. In addition, it is possible to reduce the electric resistance of the IDT electrode 9A.

Furthermore, in the present modification, the region on the piezoelectric substrate 2 can efficiently be utilized as in the first example embodiment.

Here, of the first busbar 13A and the second busbar 14A, at least the first busbar 13A needs to be provided with the offset electrodes. In other words, of the first offset electrodes 11 and the second offset electrodes 12, at least the first offset electrodes 11 only need to be provided thereto. In this way, it is possible to obtain effects of reflecting the main mode to the intersecting region A side and reducing or preventing a leakage of the main mode.

Alternatively, in another example embodiment of the present invention, each busbar of the IDT electrode need not be provided with the multiple apertures or the multiple offset electrodes.

Referring back to FIG. 2, examples of materials of the respective members in the piezoelectric substrate 2 will be shown below.

A piezoelectric material such as aluminum nitride, lithium tantalate, lithium niobate, or quartz, a ceramic such as alumina, sapphire, magnesia, silicon nitride, silicon carbide, zirconia, cordierite, mullite, steatite, forsterite, spinel, or SiALON, a dielectric material such as aluminum oxide, silicon oxynitride, DLC (diamond-like carbon), or diamond, a semiconductor such as silicon, or a material including any of the aforementioned materials as a principal component can also be used as a material of the support substrate 4, for example. Note that an aluminum compound including oxygen and one or more elements selected from the group consisting of Mg, Fe, Zn, Mn, and the like is included in the aforementioned spinel. It is possible to cite MgAl₂O₄, FeAl₂O₄, ZnAl₂O₄, and MnAl₂O₄ as examples of the above-mentioned spinel. High resistivity silicon is preferably used for the support substrate 4. The material of the support substrate 4 preferably has volume resistivity equal to or above about 1000 Ω·cm, for example. In the first example embodiment, high resistivity silicon is used as the material of the support substrate 4, for example.

The first layer 5a of the intermediate layer 5 is a high acoustic velocity film. The high acoustic velocity film is a film that involves a relatively high acoustic velocity. More specifically, an acoustic velocity of a bulk wave propagating on the high acoustic velocity film is higher than an acoustic velocity of an acoustic wave propagating on the piezoelectric layer 6. A piezoelectric material such as aluminum nitride, lithium tantalate, lithium niobate, or quartz, a ceramic such as alumina, sapphire, magnesia, silicon nitride, silicon carbide, zirconia, cordierite, mullite, steatite, forsterite, spinel, or SiALON, a dielectric material such as aluminum oxide, silicon oxynitride, DLC (diamond-like carbon), or diamond, a semiconductor such as silicon, or a material including any of the aforementioned materials as a principal component can also be used as a material of the first layer 5a, which is a high acoustic velocity film, for example. Note that an aluminum compound including oxygen and one or more elements selected from the group consisting of Mg, Fe, Zn, Mn, and the like is included in the aforementioned spinel. It is possible to cite MgAl₂O₄, FeAl₂O₄, ZnAl₂O₄, and MnAl₂O₄ as examples of the above-mentioned spinel. In the first example embodiment, silicon nitride is used as the material of the first layer 5a, for example.

The second layer 5b of the intermediate layer 5 is a low acoustic velocity film. The low acoustic velocity film is a film that involves a relatively low acoustic velocity. More specifically, an acoustic velocity of a bulk wave propagating on the low acoustic velocity film is lower than an acoustic velocity of a bulk wave propagating on the piezoelectric layer 6. A dielectric material such as glass, silicon oxide, silicon oxynitride, lithium oxide, tantalum oxide, or a compound of silicon oxide with the addition of fluorine, carbon, or boron, or a material including any of the aforementioned materials as a principal component, can be used as a material of the second layer 5b, which is a low acoustic velocity film, for example. In the first example embodiment, silicon oxide is used as the material of the second layer 5b.

For example, lithium tantalate, lithium niobate, zinc oxide, aluminum nitride, quartz, PZT (lead zirconate titanate), and the like can be used as a material of the piezoelectric layer 6 shown in FIG. 2. It is preferable to use lithium tantalate or lithium niobate as the material of the piezoelectric layer 6. In the first example embodiment, lithium tantalate is used as the material of the piezoelectric layer 6.

In the first example embodiment, the first layer 5a as the high acoustic velocity film, the second layer 5b as the low acoustic velocity film, and the piezoelectric layer 6 are stacked in this order in the piezoelectric substrate 2. Thus, the energy of the acoustic wave can effectively be confined to the piezoelectric layer 6 side.

For example, one or more types of metals selected from the group consisting of Ti, Mo, Ru, W, Al, Pt, Ir, Cu, Cr, and Sc may be used as a material of the IDT electrode 9, the first reflector 7, and the second reflector 8. The IDT electrode 9, the first reflector 7, and the second reflector 8 may include a single layer of a metallic film or from a multilayer metallic film. In the first example embodiment, Al is used as the material of the IDT electrode 9, the first reflector 7, and the second reflector 8.

In the present specification, the principal component is a component having a proportion in excess of 50% by weight. The material of the aforementioned principal component may exist in any of a single-crystal state, a polycrystalline state, and an amorphous state, or in a mixed state of these states.

In the first example embodiment, the number of the reflector electrode fingers in the first reflector 7 and the number of the reflector electrode fingers in the second reflector 8 are equal. Here, the number of the reflector electrode fingers in the first reflector 7 and the number of the reflector electrode fingers in the second reflector 8 may be different from each other. A second example embodiment of the present invention will represent this example.

FIG. 12 is a schematic plan view of an acoustic wave device according to the second example embodiment.

The present example embodiment is different from the first example embodiment in that the number of reflector electrode fingers in a first reflector 27 is smaller than the number of reflector electrode fingers in the second reflector 8. Except for the aforementioned point, the acoustic wave device of the present invention has the same configuration as the acoustic wave device 10 of the first example embodiment.

The acoustic wave device having the configuration of the second example embodiment and the acoustic wave device having the configuration of the comparative example shown in FIG. 7 were prepared and the impedance frequency characteristics and the relationships between the frequency and the Q factor thereof were compared. Design parameters of the acoustic wave device having the configuration of the second example embodiment were set as described below. Here, a dimension along the direction of extension of the electrode finger of the gap between the tip end portion of the electrode finger and the busbar will be defined as an I-B gap. In the second example embodiment, the I-B gap of the gap between the tip end portion of the second electrode finger 16 and the first busbar 13 and the I-B gap of the gap between the tip end portion of the first electrode finger 15 and the second busbar 14 are equal. In the following example design parameters, the number of pairs of the reflector electrode fingers is equivalent to the number of pairs of the reflector electrode fingers overlapping one another in the direction of extension of the propagation axis. The number of pairs of the reflector electrode fingers overlapping one another in the direction of extension of the propagation axis varies depending on the location. Accordingly, the number of pairs has a maximum value and a minimum value.
Support substrate: material . . . Si, plane orientation . . . (111), value ψ in Euler angles (φ, θ, ψ) . . . 73°
First layer of intermediate layer: material . . . SiN, thickness . . . 300 nm
Second layer of intermediate layer: material . . . SiO₂, thickness . . . 300 nm
Piezoelectric layer: material . . . rotated Y-cut 55° X-propagating LiTaO₃, thickness . . . 400 nm
IDT electrode: material . . . Al, thickness 100 nm
Dielectric film: material . . . SiO₂, thickness . . . 30 nm
Maximum value of excitation angle θ_{C_prop}: 15.9°
Intersection angle θ_{C1_AP}: 0°
Intersection angle θ_{C2_AP}: 0°
Wavelength λ: 2.09μm at portion where excitation angle θ_{C_prop} is equal to 0°
Number of pairs of electrode fingers of IDT electrode: 151 pairs
Duty ratio: 0.5 at portion where excitation angle θ_{C_prop} is equal to 0°
I-B gap: 0.27 μm
Number of pairs of reflector electrode fingers in first reflector: equal to or above 9 pairs and equal to or below 15 pairs
Number of pairs of reflector electrode fingers in second reflector: equal to or above 15 pairs and equal to or below 20 pairs

Design parameters in the comparative example were the same as the design parameters in the first example embodiment except that the number of pairs of the reflector electrode fingers in the second reflector was set equal to 15 pairs.

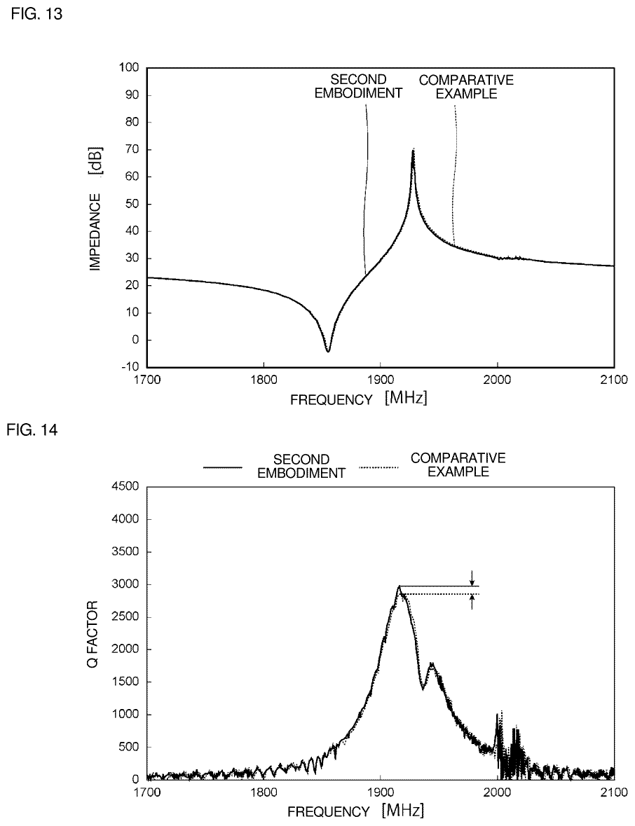

FIG. 13 is a diagram showing the impedance frequency characteristics in the second example embodiment and in the comparative example. FIG. 14 is a diagram showing relationships between the frequency and the Q factor in the second example embodiment and in the comparative example.

As shown in FIG. 13, the impedance frequency characteristics are not very different between the second example embodiment and the comparative example. On the other hand, as shown in FIG. 14, a maximum value of the Q factor in the second example embodiment is larger than that in the comparative example. It is possible to increase the Q factor in the case where the number of the reflector electrode fingers in the first reflector 27 and the number of the reflector electrode fingers in the second reflector 8 are different from each other as in the second example embodiment shown in FIG. 12.

In addition, as in the first example embodiment, it is possible to reduce the area of the region corresponding to the blank region B shown in FIG. 7 in the second example embodiment as well. Hence, the acoustic wave can suitably be confined to the IDT electrode 9 side without increasing the sizes of the first reflector 27 and the second reflector 8, thereby increasing the Q factor of the acoustic wave device. Accordingly, the region on the piezoelectric substrate 2 can efficiently be utilized.

An example embodiment of the present invention can also adopt a configuration that uses a piston mode. This example will be represented by first to third modifications of the second example embodiment. According to the first to third modifications as well, the region on the piezoelectric substrate 2 can efficiently be utilized as in the second example embodiment.

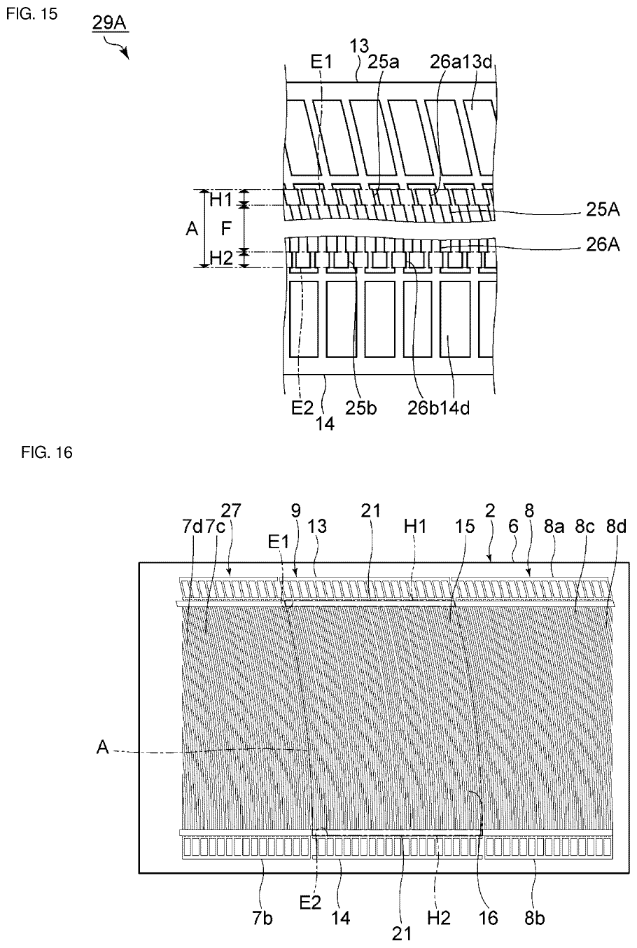

FIG. 15 is a schematic enlarged plan view showing a portion near a first busbar and a second busbar of an IDT electrode in the first modification of the second example embodiment.

Each of electrode fingers of an IDT electrode 29A includes broadened portions in the first edge region H1 and the second edge region H2. A width of the electrode finger at each broadened portion is larger than a width of the electrode finger in the central region F.

Specifically, a first electrode finger 25A includes a broadened portion 25a in the first edge region H1. A second electrode finger 26A also includes a broadened portion 26a in the first edge region H1. Meanwhile, the first electrode finger 25A includes a broadened portion 25b in the second edge region H2. The second electrode finger 26A also includes a broadened portion 26b in the second edge region H2. Accordingly, the acoustic velocities in the first edge region H1 and the second edge region H2 are lower than the acoustic velocity in the central region F. Thus, low acoustic velocity regions are provided in the first edge region H1 and the second edge region H2. The low acoustic velocity region is a region in which the acoustic velocity is lower than the acoustic velocity in the central region F.

In the present modification, the central region F and the pair of low acoustic velocity regions are disposed in this order from inside to outside in a direction of opposition of the first busbar 13 and the second busbar 14 to each other. Accordingly, the piston mode is established. This makes it possible to suppress a transverse mode which is an unnecessary wave. In addition, energy of the main mode can effectively be confined to a central side of the intersecting region A, thus achieving good characteristics of the main mode.

A configuration of the IDT electrode 29A is the same as that of the second example embodiment except for the first edge region H1 and the second edge region H2.

Here, at least one electrode finger includes the broadened portion in at least one of the first edge region H1 and the second edge region H2. Nonetheless, it is preferable that multiple electrode fingers include the broadened portions in at least one of the first edge region H1 and the second edge region H2, and it is more preferable that all of the electrode fingers therein have the broadened portions. Moreover, it is more preferable that multiple electrode fingers include the broadened portions in both of the first edge region H1 and the second edge region H2, and it is even more preferable that all of the electrode fingers therein include the broadened portions. Thus, it is possible to establish the piston mode more reliably.

Shapes in plan view of the multiple electrode fingers of the IDT electrode 29A are shapes that can be approximated to arcs. Nonetheless, the configuration in which the low acoustic velocity region is provided in the first edge region H1 or the second edge region H2 can also be adopted to another configuration of an example embodiment of the present invention which involves shapes of the electrode fingers different from those of the present modified example.

In the IDT electrode 29A, a width of each electrode finger is broadened across the entire edge region. A shape in plan view of each broadened portion is a quadrangle. Nonetheless, each electrode finger may be broadened at least partially in each edge region. The shape in plan view of each broadened portion is not limited to the quadrangle.

Although not illustrated, each reflector electrode finger of the first reflector and the second reflector also has a broadened portion in a region formed by extending each edge region in the direction of extension of each edge region. That is to say, in each reflector electrode finger, a width at a portion located in the region is larger than a width of the remaining portion. Note that each reflector electrode finger does not have to have the broadened portion.

In the second modification shown in FIG. 16, low acoustic velocity regions are provided in the first edge region H1 and the second edge region H2 by providing a pair of mass addition films 21. Specifically, one of the pair of mass addition films 21 is provided to the first edge region H1. Another one of the mass addition films 21 is provided to the second edge region H2. In the present modification, the configuration of the IDT electrode 9 is the same as that of the second example embodiment.

Each mass addition film 21 has a belt shape. Each of the pair of mass addition films 21 is continuously provided across the multiple electrode fingers in the IDT electrode 9. Accordingly, each mass addition film 21 is also provided at portions between the electrode fingers on the piezoelectric substrate 2. An appropriate dielectric material can be used as a material of the mass addition films 21.

Here, the mass addition film 21 only needs to be stacked on at least one electrode finger out of the multiple electrode fingers in at least one of the first edge region H1 and the second edge region H2. Specifically, the mass addition film 21 only needs to be provided in such a way as to overlap at least one of the first electrode fingers 15 and the second electrode fingers 16 in plan view in at least one of the first edge region H1 and the second edge region H2. In this case, the low acoustic velocity region is provided in at least a portion of at least one of the first edge region H1 and the second edge region H2.

It is preferable that multiple electrode fingers be stacked with the mass addition films 21 in at least one of the first edge region H1 and the second edge region H2, and it is more preferable that all of the electrode fingers therein be stacked with the mass addition films 21. Moreover, it is more preferable that multiple electrode fingers be stacked with the mass addition films 21 in both of the first edge region H1 and the second edge region H2, and it is even more preferable that all of the electrode fingers therein be stacked with the mass addition films 21. Thus, it is possible to establish the piston mode more reliably.

At a portion where the electrode finger and the mass addition film 21 are stacked, the piezoelectric substrate 2, the electrode finger, and the mass addition film 21 are stacked in this order. Nonetheless, at the portion where the electrode finger and the mass addition film 21 are stacked, the piezoelectric substrate 2, the mass addition film 21, and the electrode finger may be stacked in this order. That is to say, the mass addition film 21 may be provided between the piezoelectric substrate 2 and the electrode finger.

In the case where the dielectric film 18 shown in FIG. 2 is provided, the dielectric film 18 may cover the mass addition film 21 or the mass addition film 21 may be provided on the dielectric film 18. In the case where the mass addition film 21 is provided on the dielectric film 18, an appropriate metal or an appropriate dielectric material can be used as a material of the mass addition film 21.

In the present modification, the mass addition film 21 is also provided in each region formed by extending each edge region in the direction of extension of each edge region. Accordingly, the portions located in the respective regions of the respective reflector electrode fingers of the first reflector 27 and the second reflector 8 are stacked with the mass addition films 21. Here, the respective reflector electrode fingers do not have to be stacked with the mass addition films 21.

In the present modification, each edge region is provided with one mass addition film 21. Nonetheless, each edge region may be provided with multiple mass addition films 21. For example, in the first edge region H1, the mass addition films 21 may be provided on each of the first electrode fingers 15 and on each of the second electrode fingers 16. More specifically, each mass addition film 21 may be provided only on one electrode finger. The same applies to the second edge region H2. In this case, an appropriate metal or an appropriate dielectric material can be used as a material of the mass addition films 21.

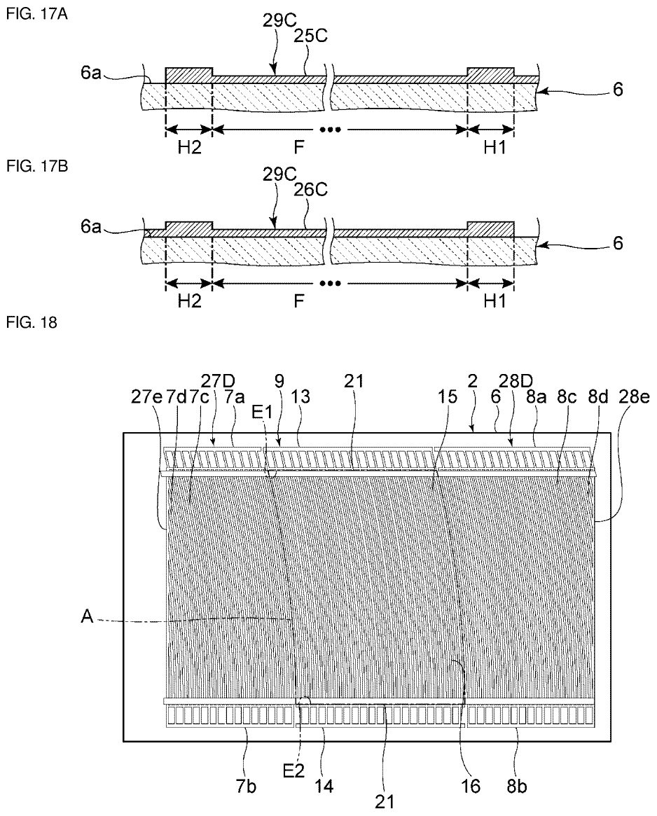

In the case where each mass addition film 21 is provided only on one electrode finger, for example, the same material as the metal used for the respective electrode fingers may be used as the material of the mass addition films 21. This configuration corresponds to a configuration of a third modification shown in FIGS. 17A and 17B. Specifically, as shown in FIG. 17A in an IDT electrode 29C, thicknesses of a first electrode finger 25C in the first edge region H1 and the second edge region H2 are larger than a thickness of the first electrode finger 25C in the central region F. As shown in FIG. 17B, thicknesses of a second electrode finger 26C in the first edge region H1 and the second edge region H2 are larger than a thickness of the second electrode finger 26C in the central region F. In this way, the low acoustic velocity regions are provided in the first edge region H1 and the second edge region H2.

Note that FIG. 17A schematically shows a cross-section of the first electrode finger 25C taken along a direction of extension of the first electrode finger 25C. Likewise, FIG. 17B schematically shows a cross-section of the second electrode finger 26C taken along a direction of extension of the second electrode finger 26C. A configuration of the IDT electrode 29C is the same as that of the second example embodiment except for the first edge region H1 and the second edge region H2.

The thickness of at least one electrode finger in at least one of the first edge region H1 and the second edge region H2 only needs to be larger than the thickness of the electrode finger in the central region F. Nonetheless, it is preferable that the thicknesses of the multiple electrode fingers in at least one of the first edge region H1 and the second edge region H2 be larger than the thicknesses of the electrode fingers in the central region F. It is more preferable that the thicknesses of all of the electrode fingers in at least one of the first edge region H1 and the second edge region H2 be larger than the thicknesses of the electrode fingers in the central region F.

Moreover, it is more preferable that the thicknesses of multiple electrode fingers in both of the first edge region H1 and the second edge region H2 be larger than the thicknesses of the electrode fingers in the central region F. It is even more preferable that the thicknesses of all of the electrode fingers in both of the first edge region H1 and the second edge region H2 be larger than the thicknesses of the electrode fingers in the central region F. Thus, it is possible to establish the piston mode more reliably.

In the present modification, the thickness of each electrode finger is increased in the entire edge region. Nonetheless, the thickness of each electrode finger may be at least partially increased in each edge region.

Although not illustrated, in each of the reflector electrode fingers of the first reflector and the second reflector, a thickness of a portion located in a region formed by extending each edge region in the direction of extension of each edge region is larger than a thickness of the remaining portion. Here, the thickness of each reflector electrode finger does not have to be large in each edge region.

The low acoustic velocity region only needs to be provided in accordance with the configuration of at least any of the first to third modifications. For example, the low acoustic velocity region may be provided in accordance with multiple configurations out of the first to third modifications.

Referring back to FIG. 12, in the second example embodiment, one end portion of each of the second reflector electrode fingers 7d is not connected to an electrode. Nonetheless, the one end portion may be connected to an electrode.

For example, in a fourth modification of the second example embodiment shown in FIG. 18, a first reflector 27D includes an end portion connection electrode 27e. The end portion connection electrode 27e is connected to both of the first reflector busbar 7a and the second reflector busbar 7b. Moreover, one end portion of each of the multiple second reflector electrode fingers 7d is directly connected to the end portion connection electrode 27e. Thus, the one end portion of each of the second reflector electrode fingers 7d is indirectly connected to the first reflector busbar 7a via the end portion connection electrode 27e. Another end portion of each of the second reflector electrode fingers 7d is directly connected to the second reflector busbar 7b.

In the present modification, a second reflector 28D also includes an end portion connection electrode 28e. The end portion connection electrode 28e is connected to both of the third reflector busbar 8a and the fourth reflector busbar 8b. One end portion of each of the multiple fourth reflector electrode fingers 8d is directly connected to the third reflector busbar 8a. Another end portion of each of the fourth reflector electrode fingers 8d is directly connected to the end portion connection electrode 28e. Thus, the other end portion of each of the fourth reflector electrode fingers 8d is indirectly connected to the fourth reflector busbar 8b via the end portion connection electrode 28e.

In the present modification as well, the region on the piezoelectric substrate 2 can efficiently be utilized as in the second example embodiment. In addition, in the first reflector 27D, it is possible to short-circuit the second reflector electrode fingers 7d by using the end portion connection electrode 27e. In the second reflector 28D, it is possible to short-circuit the fourth reflector electrode fingers 8d by using the end portion connection electrode 28e.

Shapes in plan view of the end portion connection electrode 27e and the end portion connection electrode 28e are linear shapes. More specifically, in the first reflector 27D, an angle between a direction of extension of the end portion connection electrode 27e and the direction of extension of the first reflector busbar 7 a is equal to or above about 45° and equal to or below about 135°, for example. Thus, it is possible to further reduce the area of the region corresponding to the blank region B shown in FIG. 7. Accordingly, the region on the piezoelectric substrate 2 can be utilized more efficiently.

Likewise, in the second reflector 28D, an angle between a direction of extension of the end portion connection electrode 28e and the direction of extension of the third reflector busbar 8 a is equal to or above about 45° and equal to or below about 135°, for example. Thus, it is possible to further reduce the area of the region corresponding to the blank region B shown in FIG. 7. Accordingly, the region on the piezoelectric substrate 2 can be utilized more efficiently. Nonetheless, the shapes in plan view of the end portion connection electrode 27e and the end portion connection electrode 28e may be curved shapes.

The first reflector only needs to include at least one second reflector electrode finger. In the case where the second reflector includes the fourth reflector electrode finger, the second reflector only needs to include at least one fourth reflector electrode finger.

For example, in the first reflector 27D of the present modification, the one end portion of at least one second reflector electrode finger 7d needs to be indirectly connected to the first reflector busbar 7a via the end portion connection electrode 27e. The other end portion of the second reflector electrode finger 7d only needs to be directly connected to the second reflector busbar 7b. In the second reflector 28D, the one end portion of at least one fourth reflector electrode finger 8d needs to be directly connected to the third reflector busbar 8a. The other end portion of the fourth reflector electrode finger 8d only needs to be indirectly connected to the fourth reflector busbar 8b via the end portion connection electrode 28e.

In the present modification, the pair of mass addition films 21 are provided as in the second modification. Here, the mass addition films 21 do not have to be provided.

In the second example embodiment shown in FIG. 12, the second reflector 8 includes the fourth reflector electrode fingers 8d. Nonetheless, the second reflector 8 does not necessarily have to include the fourth reflector electrode fingers 8d.

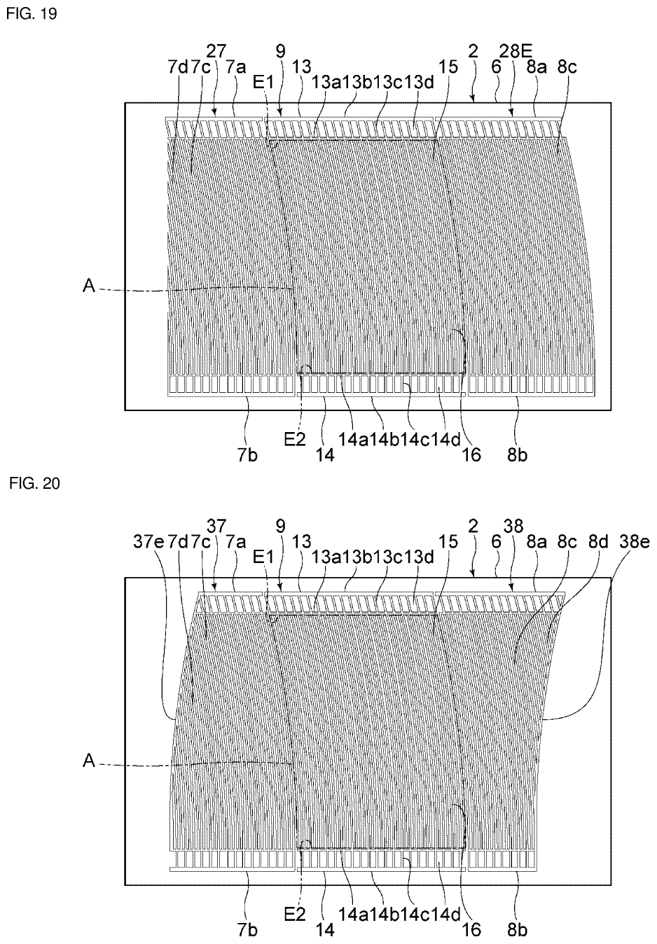

For example, in a fifth modification of the second example embodiment shown in FIG. 19, a second reflector 28E does not include a fourth reflector electrode finger. Multiple reflector electrode fingers of the second reflector 28E include only the third reflector electrode fingers 8c. One end portion of each of the third reflector electrode fingers 8c is directly connected to the third reflector busbar 8a, while another end portion thereof is directly connected to the fourth reflector busbar 8b.

In this modification as well, the acoustic wave can suitably be confined to the IDT electrode 9 side without increasing the size of the first reflector 27, thus increasing the Q factor of the acoustic wave device. Accordingly, the region on the piezoelectric substrate 2 can efficiently be utilized.

Referring back to FIG. 12, in the second example embodiment, at least a portion of each second reflector electrode finger 7d overlaps both of the first reflector busbar 7a and the second reflector busbar 7b when viewed from the first reflector busbar opposing direction. Nonetheless, all of the second reflector electrode fingers 7d only need to overlap at least one of the first reflector busbar 7a and the second reflector busbar 7b when viewed from the first reflector busbar opposing direction.

FIG. 20 is a schematic plan view of an acoustic wave device according to a third example embodiment of the present invention.

Configurations of a first reflector 37 and a second reflector 38 of the present example embodiment are different from those of the first example embodiment. The number of reflector electrode fingers in the first reflector 37 is equal to the number of reflector electrode fingers in the second reflector 38. Except for the aforementioned point, the acoustic wave device of the present example embodiment has the same configuration as the acoustic wave device 10 of the first example embodiment.

The first reflector 37 includes an end portion connection electrode 37e. A shape in plan view of the end portion connection electrode 37e is a curved shape. Specifically, the end portion connection electrode 37e is connected to both of the first reflector busbar 7a and the second reflector busbar 7b. The end portion connection electrode 37e extends so as to approach the IDT electrode 9 in a direction from the second reflector busbar 7b side toward the first reflector busbar 7a side. Moreover, one end portion of each of the second reflector electrode fingers 7d is directly connected to the end portion connection electrode 37e. In this way, the one end portion of each of the second reflector electrode fingers 7d is indirectly connected to the first reflector busbar 7a via the end portion connection electrode 37e. Another end portion of each of the second reflector electrode fingers 7d is directly connected to the second reflector busbar 7b.

In the first reflector 37, the length of the second reflector busbar 7b is larger than the length of the first reflector busbar 7a. More specifically, when viewed from the first reflector busbar opposing direction, neither the end portion of the second reflector busbar 7b on the side closer to the IDT electrode 9 nor the end portion thereof on the side farther from the IDT electrode 9 overlaps the first reflector busbar 7a.

In addition, when viewed from the first reflector busbar opposing direction, some of the second reflector electrode fingers 7d among all of the second reflector electrode fingers 7d do not overlap the first reflector busbar 7a.

In the meantime, when viewed from the first reflector busbar opposing direction, the entire portions of all of the second reflector electrode fingers 7d overlap the second reflector busbar 7b. Thus, it is possible to reduce or prevent an increase in area of the first reflector 37 even when the multiple second reflector electrode fingers 7d are provided.

Moreover, in the entire region of the first reflector 37, the direction of propagation of the acoustic wave is the direction toward the second reflector busbar 7b side, and the number of the reflector electrode fingers increases in the region toward the second reflector busbar 7b side. Hence, the acoustic wave can suitably be confined to the IDT electrode 9 side by using the first reflector 37, and the Q factor of the acoustic wave device can be increased. Accordingly, the region on the piezoelectric substrate 2 can efficiently be used.

In the present example embodiment, the second reflector 38 also includes an end portion connection electrode 38e. A shape in plan view of the end portion connection electrode 38e is a curved shape. Specifically, the end portion connection electrode 38e is connected to both of the third reflector busbar 8a and the fourth reflector busbar 8b. The end portion connection electrode 38e extends so as to approach the IDT electrode 9 in a direction from the third reflector busbar 8a side toward the fourth reflector busbar 8b side. Moreover, one end portion of each of the fourth reflector electrode fingers 8d is directly connected to the third reflector busbar 8a, and another end portion thereof is directly connected to the end portion connection electrode 38e. In this way, the other end portion of each of the fourth reflector electrode fingers 8d is connected indirectly to the fourth reflector busbar 8b via the end portion connection electrode 38e.

In the second reflector 38, the length of the third reflector busbar 8a is larger than the length of the fourth reflector busbar 8b. More specifically, when viewed from the second reflector busbar opposing direction, neither the end portion of the third reflector busbar 8a on the side closer to the IDT electrode 9 nor the end portion thereof on the side farther from the IDT electrode 9 overlaps the fourth reflector busbar 8b.

In addition, when viewed from the second reflector busbar opposing direction, some of the fourth reflector electrode fingers 8d among all of the fourth reflector electrode fingers 8d do not overlap the fourth reflector busbar 8b.

In the meantime, when viewed from the second reflector busbar opposing direction, the entire portions of all of the fourth reflector electrode fingers 8d overlap the third reflector busbar 8a. Thus, it is possible to reduce or prevent an increase in area of the second reflector 38 even when the multiple fourth reflector electrode fingers 8d are provided.

Moreover, in the entire region of the second reflector 38, the direction of propagation of the acoustic wave is the direction toward the third reflector busbar 8a side, and the number of the reflector electrode fingers increases in the region toward the third reflector busbar 8a side. Hence, the acoustic wave can suitably be confined to the IDT electrode 9 side by using the second reflector 38, and the Q factor of the acoustic wave device can be increased.

Since the first reflector 37 and the second reflector 38 have the above-described configurations, the region on the piezoelectric substrate 2 can be utilized more efficiently. Note that the multiple reflector electrode fingers of the second reflector 38 do not necessarily have to include the fourth reflector electrode fingers 8d.

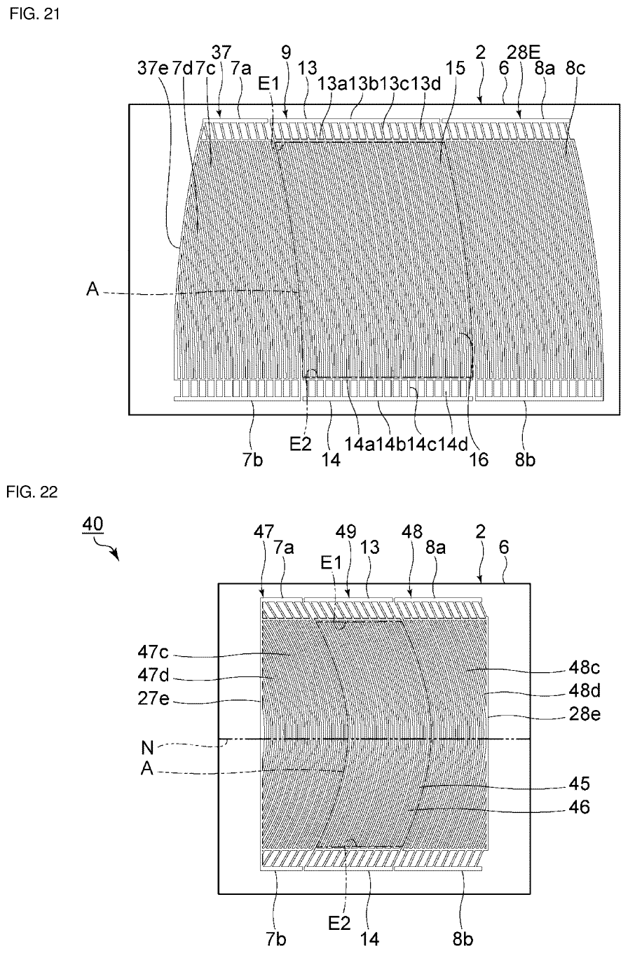

For example, in a modification of the third example embodiment shown in FIG. 21, the first reflector 37 is configured in the same manner as in the third example embodiment. On the other hand, the second reflector 28E does not include the fourth reflector electrode fingers. The multiple reflector electrode fingers of the second reflector 28E only include the third reflector electrode fingers 8c. One end portion of each of the third reflector electrode fingers 8c is directly connected to the third reflector busbar 8a, and another end portion thereof is directly connected to the fourth reflector busbar 8b.

In this modification as well, the acoustic wave can suitably be confined to the IDT electrode 9 side without increasing the size of the first reflector 37, thereby increasing the Q factor of the acoustic wave device. Accordingly, the region on the piezoelectric substrate 2 can efficiently be utilized.

In the first to third example embodiments and the respective modifications thereof, the shapes in plan view of the multiple electrode fingers of the IDT electrode are convex on the second reflector side and convex on the first busbar side. The shapes in plan view of the multiple reflector electrode fingers in the first reflector and the second reflector also have shapes that correspond to the shapes in plan view of the multiple electrode fingers.

Specifically, the shapes in plan view of the multiple reflector electrode fingers of the first reflector are shapes that are convex toward the IDT electrode side and convex on the first reflector busbar side. The shapes in plan view of the multiple reflector electrode fingers of the second reflector are convex away from the IDT electrode and convex on the third reflector busbar side.

The directions of propagation of the acoustic wave in the first reflector and the second reflector are directions indicated with the curved arrow L1 and the curved arrow L2 in FIG. 6, for example, due to the shapes of the multiple electrode fingers in the IDT electrode as well as the multiple reflector electrode fingers in the first reflector and the second reflector. More specifically, the direction of propagation of the acoustic wave is the direction toward the second reflector busbar side in the entire region of the first reflector. The direction of propagation of the acoustic wave is the direction toward the third reflector busbar side in the entire region of the second reflector.

Nonetheless, the first reflector may include a region in which the direction of propagation of the acoustic wave is a direction toward the first reflector busbar side. On the other hand, the second reflector may include a region in which the direction of propagation of the acoustic wave is a direction toward the fourth reflector busbar side. This example will be represented by a fourth example embodiment of the present invention.

FIG. 22 is a schematic plan view of an acoustic wave device according to the fourth example embodiment.

Shapes of an IDT electrode 49, a first reflector 47, and a second reflector 48 of the present example embodiment are different from those of the first example embodiment. The present example embodiment is also different from the first example embodiment in that the first reflector 47 includes the end portion connection electrode 27e and the second reflector 48 includes the end portion connection electrode 28e. Except for the aforementioned points, an acoustic wave device 40 of the present example embodiment has the same configuration as the acoustic wave device 10 of the first example embodiment.

A two-dot chain line N in FIG. 22 extends parallel to the direction of extension of the propagation axis. The two-dot chain line N passes through the center of the intersecting region A. A region on the first busbar 13 side relative to the two-dot chain line N is formed in the same manner as in the first example embodiment. Accordingly, in the region on the first busbar 13 side relative to the two-dot chain line N, shapes in plan view of multiple first electrode fingers 45 and multiple second electrode fingers 46 are shapes that are convex on the second reflector 48 side and convex on the first busbar 13 side. Meanwhile, in the region on the second busbar 14 side relative to the two-dot chain line N in the IDT electrode 49, shapes in plan view of the first electrode fingers 45 and the second electrode fingers 46 are shapes that are convex on the second reflector 48 side and convex on the second busbar 14 side.

Each of the first reflector 47 and the second reflector 48 includes two regions that use the two-dot chain line N as a boundary. In the following, the two-dot chain line N may be referred to as a boundary line when appropriate. In the region of the first reflector 47 on the first reflector busbar 7a side relative to the boundary line, shapes in plan view of the multiple reflector electrode fingers are shapes that are convex toward the IDT electrode 49 and convex on the first reflector busbar 7a side. In the region of the first reflector 47 on the second reflector busbar 7b side relative to the boundary line, shapes in plan view of the multiple reflector electrode fingers are shapes that are convex toward the IDT electrode 49 side and convex on the second reflector busbar 7b side.

In the first reflector 47, one end portion of each of multiple first reflector electrode fingers 47c is connected to the first reflector busbar 7a. Another end portion of each of the first reflector electrode fingers 47c is connected to the second reflector busbar 7b.

The end portion connection electrode 27e of the first reflector 47 is connected to both of the first reflector busbar 7a and the second reflector busbar 7b. The shape in plan view of the end portion connection electrode 27e is the linear shape. Moreover, two end portions of each of second reflector electrode fingers 47d are directly connected to the end portion connection electrode 27e. Thus, the two end portions of each of the second reflector electrode fingers 47d are indirectly connected to the first reflector busbar 7a and the second reflector busbar 7b via the end portion connection electrode 27e. In other words, one end portion of each of the second reflector electrode fingers 47d is indirectly connected to the first reflector busbar 7a via the end portion connection electrode 27e. The other end portion of each of the second reflector electrode fingers 47d is indirectly connected to the second reflector busbar 7b via the end portion connection electrode 27e.

In the present example embodiment, when viewed from the first reflector busbar opposing direction, the entire portions of all of the second reflector electrode fingers 47d overlap both of the first reflector busbar 7a and the second reflector busbar 7b. The direction of propagation of the acoustic wave is the direction toward the second reflector busbar 7b side in a partial region of the first reflector 47, and the number of the reflector electrode fingers increases in the region toward the second reflector busbar 7b side. In addition, in another partial region, the direction of propagation of the acoustic wave is the direction toward the first reflector busbar 7a side, and the number of the reflector electrode fingers increases in the region toward the first reflector busbar 7a side.

In the present example embodiment, the above-described configuration makes it possible to suitably confine the acoustic wave to the IDT electrode 49 side without increasing the size of the first reflector 47, and to increase the Q factor of the acoustic wave device 40. Thus, the region on the piezoelectric substrate 2 can efficiently be utilized.

In the second reflector 48, one end portion of each of multiple third reflector electrode fingers 48c is connected to the third reflector busbar 8a. Another end portion of each of the third reflector electrode fingers 48c is connected to the fourth reflector busbar 8b.

The end portion connection electrode 28e of the second reflector 48 is connected to both of the third reflector busbar 8a and the fourth reflector busbar 8b. The shape in plan view of the end portion connection electrode 28e is the linear shape. Moreover, in a region of the second reflector 48 on the third reflector busbar 8a side relative to the two-dot chain line N serving as the boundary line, one end portion of each of multiple fourth reflector electrode fingers 48d is directly connected to the third reflector busbar 8a. Another end portion of each of the fourth reflector electrode fingers 48d is directly connected to the end portion connection electrode 28e. Thus, the other end portion of each of the fourth reflector electrode fingers 48d is indirectly connected to the fourth reflector busbar 8b via the end portion connection electrode 28e.

In a region of the second reflector 48 on the fourth reflector busbar 8b side relative to the boundary line, the one end portion of each of the fourth reflector electrode fingers 48d is directly connected to the end portion connection electrode 28e. Thus, the one end portion of each of the fourth reflector electrode fingers 48d is indirectly connected to the third reflector busbar 8a via the end portion connection electrode 28e. The other end portion of each of the fourth reflector electrode fingers 48d is directly connected to the fourth reflector busbar 8b.

In the present example embodiment, when viewed from the second reflector busbar opposing direction, the entire portions of all of the fourth reflector electrode fingers 48d overlap both of the third reflector busbar 8a and the fourth reflector busbar 8b. The direction of propagation of the acoustic wave is the direction toward the third reflector busbar 8a side in a partial region of the second reflector 48, and the number of the reflector electrode fingers increases in the region toward the third reflector busbar 8a side. In addition, in another partial region, the direction of propagation of the acoustic wave is the direction toward the fourth reflector busbar 8b, and the number of the reflector electrode fingers increases in the region toward the fourth reflector busbar 8b side. Thus, the acoustic wave can suitably be confined to the IDT electrode 49 side without increasing the size of the second reflector 48, and the Q factor of the acoustic wave device 40 can be increased.

Since the first reflector 47 and the second reflector 48 have the above-described configurations, the region on the piezoelectric substrate 2 can be utilized more efficiently.

Here, in the first reflector 47, the one end portion of at least one second reflector electrode finger 47d only needs to be indirectly connected to the first reflector busbar 7a via the end portion connection electrode 27e. The other end portion of the second reflector electrode finger 47d only needs to be indirectly connected to the second reflector busbar 7b via the end portion connection electrode 27e.

In the second reflector 48, the one end portion of at least one fourth reflector electrode finger 48d in a partial region only needs to be directly connected to the third reflector busbar 8a. The other end portion of the fourth reflector electrode finger 48d only needs to be indirectly connected to the fourth reflector busbar 8b via the end portion connection electrode 28e. In the second reflector 48, the one end portion of at least one fourth reflector electrode finger 48d in another partial region only needs to be indirectly connected to the third reflector busbar 8a via the end portion connection electrode 28e. The other end portion of the fourth reflector electrode finger 48d only needs to be directly connected to the fourth reflector busbar 8b.

Shapes in plan view of the multiple electrode fingers of the IDT electrode 49 as well as the multiple reflector electrode fingers of the first reflector 47 and the second reflector 48 are shapes that can be approximated to the arcs. The respective electrode fingers of the IDT electrode 49 as well as the respective reflector electrode fingers of the first reflector 47 and the second reflector 48 each include a portion located in one region and a portion located in another region out of two regions defined by using the two-dot chain line N as the boundary.

Moreover, regarding any electrode finger of the IDT electrode 49, a shape in plan view of a portion located in the one region and a shape in plan view of a portion located in the other region are shapes that can be approximated to the same arc. Likewise, regarding any reflector electrode finger of the first reflector 47 and the second reflector 48, a shape in plan view of a portion located in the one region and a shape in plan view of a portion located in the other region are shapes that can be approximated to the same arc.

Nonetheless, the shapes in plan view of the respective electrode fingers of the IDT electrode 49 as well as the respective reflector electrode fingers of the first reflector 47 and the second reflector 48 are not limited to the above-mentioned shapes. The shapes in plan view of the respective electrode fingers and the respective reflector electrode fingers may be, for example, shapes that can be approximated to elliptic arcs, parabolic shapes that cannot be approximated to arcs or elliptic arcs, arc shapes, or elliptic arc shapes.

In the present example embodiment, the shapes in plan view of the multiple electrode fingers in the intersecting region A are shapes that can be approximated to a single arc. In this case, there is one curved region in the intersecting region A. This also applies to the first to third example embodiments and the respective modifications thereof. Here, the intersecting region A may include multiple curved regions. This example will be represented by a fifth example embodiment of the present invention.

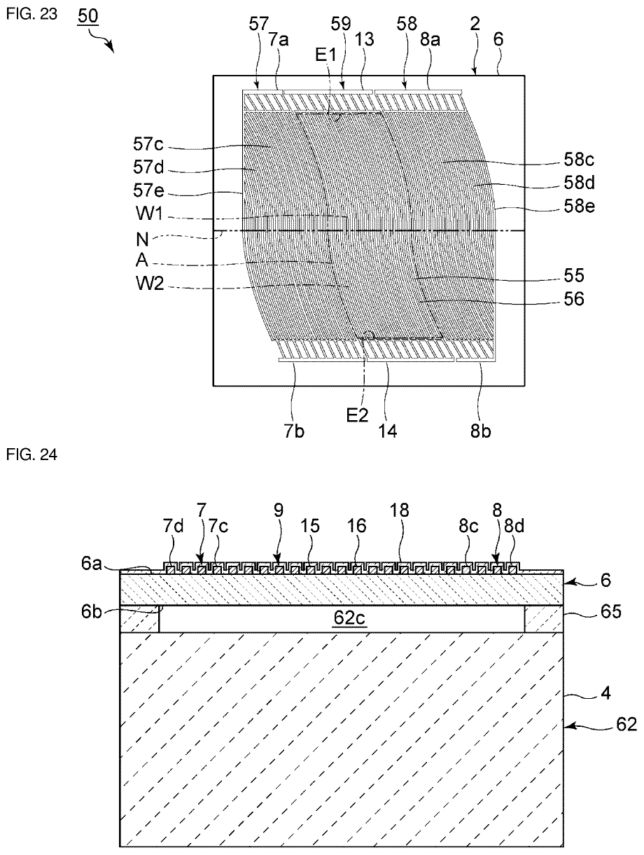

FIG. 23 is a schematic plan view of an acoustic wave device according to the fifth example embodiment.

The present example embodiment is different from the first example embodiment in that the intersecting region A includes multiple curved regions. More specifically, the multiple curved regions in the present example embodiment are a first curved region W1 and a second curved region W2. Shapes of multiple reflector electrode fingers of a first reflector 57 and a second reflector 58 are supposed to be shapes corresponding to multiple electrode fingers of an IDT electrode 59. Except for the aforementioned points, an acoustic wave device 50 of the present example embodiment has the same configuration as the acoustic wave device 10 of the first example embodiment.

In the acoustic wave device 50, a shape in plan view of each of first electrode fingers 55 and second electrode fingers 56 includes an inflection point. In the present specification, the inflection point is a point where mutually different curved lines are connected to each other or a point where a curved line is connected to a straight line. In a case where the mutually different curved lines are connected to each other at the inflection point, directions of curved shapes are changed at the inflection point as a boundary. Such mutually different directions of curved shapes mean a state in which directions of curves in the curved shapes are different from each other, for instance. A direction of a curve stated herein is a direction of a curve that defines a convex shape on the first reflector 57 side or a direction of a curve that defines a convex shape on the second reflector 58 side. In the present example embodiment, shapes of the two curves are inverted from each other at the inflection point as a boundary.

Specifically, a shape in plan view of each of the first electrode fingers 55 and the second electrode fingers 56 includes two portions each of which can be approximated to an arc. Moreover, a shape in plan view of each electrode finger has a shape formed by connecting the two portions to each other. The center of a circle including one of the aforementioned arcs and the center of a circle including another one of the aforementioned arcs are opposed to each other with the IDT electrode 59 interposed therebetween. In the shape in plan view of each electrode finger, the inflection point is the portion where the above-described two portions are connected to each other.

One edge in the first curved region W1 is the first envelope E1. Another edge in the first curved region W1 is a boundary between the first curved region W1 and the second curved region W2. One edge in the second curved region W2 is the second envelope E2. Another edge in the second curved region W2 is the boundary between the first curved region W1 and the second curved region W2. In the respective curved regions, the shapes in plan view of the first electrode fingers 55 and the second electrode fingers 56 are shapes that can be approximated to a single arc. The boundary between the first curved region W1 and the second curved region W2 passes through the inflection points of the respective electrode fingers.

In the present example embodiment, the boundary between the first curved region W1 and the second curved region W2 is located at a portion in FIG. 23 where the two-dot chain line N passes. In other words, the inflection points of the multiple electrode fingers in the IDT electrode 59 are arrayed on the two-dot chain line N. The two-dot chain line N extends parallel to the direction of extension of the propagation axis, and passes through the center of the intersecting region A. Nonetheless, the boundary between the curved regions may extend obliquely with respect to the propagation axis.

As shown in FIG. 23, each of the multiple reflector electrode fingers in the first reflector 57 and the second reflector 58 includes an inflection point. Shapes of the two curves are inverted from each other at the inflection point as a boundary. A direction of a curve stated herein is either a direction of a curve that is convex toward the IDT electrode 59 or a direction of a curve that is convex away from the IDT electrode 59. The inflection points of the multiple reflector electrode fingers in the first reflector 57 and the second reflector 58 are arrayed on the two-dot chain line N. Moreover, each of the first reflector 57 and the second reflector 58 includes the two regions that use the two-dot chain line N as the boundary. In the following, the two-dot chain line N may be referred to as the boundary line when appropriate.

In a region of the first reflector 57 on the first reflector busbar 7a side relative to the boundary line, the shapes in plan view of the reflector electrode fingers are shapes that are convex toward the IDT electrode 59 and convex on the first reflector busbar 7a side. In a region of the first reflector 57 on the second reflector busbar 7b side relative to the boundary line, the shapes in plan view of the reflector electrode fingers are shapes that are convex away from the IDT electrode 59 and convex on the second reflector busbar 7b side.

In the first reflector 57, one end portion of each of multiple first reflector electrode fingers 57c is connected to the first reflector busbar 7a. Another end portion of each of the first reflector electrode fingers 57c is connected to the second reflector busbar 7b.

The first reflector 57 includes an end portion connection electrode 57e. The end portion connection electrode 57e is connected to both of the first reflector busbar 7a and the second reflector busbar 7b. The shape in plan view of the end portion connection electrode 57e is a shape in which a straight line is connected to a curved line. Specifically, a portion of the end portion connection electrode 57e having the straight shape is a portion located in a region on the first reflector busbar 7a side relative to the boundary line. A portion of the end portion connection electrode 57e having the curved shape is a portion located in a region on the second reflector busbar 7b side relative to the boundary line.

One end portion of each of multiple second reflector electrode fingers 57d is directly connected to the end portion connection electrode 57e. Thus, the one end portion of each of the second reflector electrode fingers 57d is indirectly connected to the first reflector busbar 7a via the end portion connection electrode 57e. Another end portion of each of the second reflector electrode fingers 57d is directly connected to the second reflector busbar 7b.

In a region of the first reflector 57 on the second reflector busbar 7b side relative to the boundary line, the shape in plan view of the end portion connection electrode 57e has the same shape as the shapes in plan view of the first reflector electrode fingers 57c and the second reflector electrode fingers 57d. Accordingly, the end portion connection electrode 57e fulfills a role to reflect the acoustic wave in this region as with the multiple reflector electrode fingers.

In the present example embodiment, when viewed from the first reflector busbar opposing direction, all of the second reflector electrode fingers 57d overlap at least the first reflector busbar 7a. In the region of the first reflector 57 on the first reflector busbar 7a side relative to the boundary line, the direction of propagation of the acoustic wave is the direction toward the second reflector busbar 7b side, and the number of the reflector electrode fingers increases in the region toward the second reflector busbar 7b side. Hence, the acoustic wave can suitably be confined to the IDT electrode 59 side without increasing the size of the first reflector 57, and the Q factor of the acoustic wave device 50 can be increased. Accordingly, the region on the piezoelectric substrate 2 can efficiently be utilized.

Here, in the region of the first reflector 57 on the second reflector busbar 7b side relative to the boundary line, the direction of propagation of the acoustic wave is the direction toward the second reflector busbar 7b side, and the number of the reflector electrode fingers is constant. Nonetheless, owing to the above-described configuration of the region on the first reflector busbar 7a side relative to the boundary line in the first reflector 57, it is possible to obtain the effect of suppressing the increase in size of the first reflector 57 and suitably confining the acoustic wave to the IDT electrode 59.

In the region of the second reflector 58 on the third reflector busbar 8a side relative to the boundary line, shapes in plan view of multiple reflector electrode fingers are shapes that are convex away from the IDT electrode 59 and convex on the third reflector busbar 8a side. In the region of the second reflector 58 on the fourth reflector busbar 8b side relative to the boundary line, shapes in plan view of the multiple reflector electrode fingers are shapes that are convex toward the IDT electrode 59 and convex on the fourth reflector busbar 8b side.

In the second reflector 58, one end portion of each of multiple third reflector electrode fingers 58c is connected to the third reflector busbar 8a. Another end portion of each of the third reflector electrode fingers 58c is connected to the fourth reflector busbar 8b.

The second reflector 58 includes an end portion connection electrode 58e. The end portion connection electrode 58e is connected to both of the third reflector busbar 8a and the fourth reflector busbar 8b. The shape in plan view of the end portion connection electrode 58e is a shape in which a straight line is connected to a curved line. Specifically, a portion of the end portion connection electrode 58e having the straight shape is a portion located in a region on the fourth reflector busbar 8b side relative to the boundary line. A portion of the end portion connection electrode 58e having the curved shape is a portion located in a region on the third reflector busbar 8a side relative to the boundary line.

One end portion of each of multiple fourth reflector electrode fingers 58d is directly connected to the third reflector busbar 8a. Another end portion of each of the fourth reflector electrode fingers 58d is directly connected to the end portion connection electrode 58e. Thus, the other end portion of each of the fourth reflector electrode fingers 58d is indirectly connected to the fourth reflector busbar 8b via the end portion connection electrode 58e.

In a region of the second reflector 58 on the third reflector busbar 8a side relative to the boundary line, the shape in plan view of the end portion connection electrode 58e has the same shape as the shapes in plan view of the third reflector electrode fingers 58c and the fourth reflector electrode fingers 58d. Accordingly, the end portion connection electrode 58e fulfills the role to reflect the acoustic wave in this region as with the multiple reflector electrode fingers.

In the present example embodiment, when viewed from the second reflector busbar opposing direction, all of the fourth reflector electrode fingers 58d overlap at least the fourth reflector busbar 8b. In the region of the second reflector 58 on the fourth reflector busbar 8b side relative to the boundary line, the direction of propagation of the acoustic wave is the direction toward the third reflector busbar 8a side, and the number of the reflector electrode fingers increases in the region toward the third reflector busbar 8a side. Hence, the acoustic wave can suitably be confined to the IDT electrode 59 side without increasing the size of the second reflector 58, and the Q factor of the acoustic wave device 50 can be increased.

Since the first reflector 57 and the second reflector 58 have the above-described configurations, the region on the piezoelectric substrate 2 can be utilized more efficiently.

Here, in the region of the second reflector 58 on the third reflector busbar 8a side relative to the boundary line, the direction of propagation of the acoustic wave is the direction toward the third reflector busbar 8a side, and the number of the reflector electrode fingers is constant. Nonetheless, owing to the above-described configuration of the region on the fourth reflector busbar 8b side relative to the boundary line in the second reflector 58, it is possible to obtain the effect of suppressing the increase in size of the second reflector 58 and suitably confining the acoustic wave to the IDT electrode 59.

In the multiple electrode fingers in the IDT electrode 59 as well as the multiple reflector electrode fingers in the first reflector 57 and the second reflector 58, portions that can be approximated to arcs are connected to each other at the inflection point. Here, portions that can be approximated to elliptic arcs may be connected to each other at the inflection point, for example. Meanwhile, curved lines in parabolic shapes that cannot be approximated to arcs or elliptic arcs may be connected to each other at the inflection point. Curved lines in arc shapes may be connected to each other or curved lines in elliptic arc shapes may be connected to each other at the inflection point.

In the intersecting region A, the shape in plan view of each electrode finger may include multiple inflection points. For example, the intersecting region A may include three or more curved regions. Likewise, in the first reflector 57 and the second reflector 58, the shape in plan view of each reflector electrode finger may include multiple inflection points. For example, the first reflector 57 and the second reflector 58 may each include three or more regions.

A multilayer structure of the piezoelectric substrate is not limited to the configuration shown in FIG. 2. A sixth example embodiment of the present invention will represent an example in which an acoustic wave device includes a piezoelectric substrate different from that in the first example embodiment.

FIG. 24 is a schematic elevational cross-sectional view of an acoustic wave device according to the sixth example embodiment.

A multilayer structure of a piezoelectric substrate 62 of the present example embodiment is different from that of the first example embodiment. Except for the aforementioned point, the acoustic wave device of the present example embodiment has the same configuration as the acoustic wave device 10 of the first example embodiment.

The piezoelectric substrate 62 includes the support substrate 4, an intermediate layer 65, and the piezoelectric layer 6. The intermediate layer 65 is provided on the support substrate 4. The piezoelectric layer 6 is provided on the intermediate layer 65. In the present example embodiment, the intermediate layer 65 has a frame-like shape. That is to say, the intermediate layer 65 includes a through hole. The support substrate 4 closes one end of the through hole in the intermediate layer 65. The piezoelectric layer 6 closes the other end of the through hole in the intermediate layer 65. Thus, the piezoelectric substrate 62 includes a hollow portion 62c. A portion of the piezoelectric layer 6 and a portion of the support substrate 4 are opposed to each other with the hollow portion 62c interposed therebetween.

In the present example embodiment, it is possible to reflect the main mode to the piezoelectric layer 6 side. Hence, the energy of the acoustic wave can effectively be confined to the piezoelectric layer 6 side. In addition, the region on the piezoelectric substrate 62 can efficiently be utilized as in the first example embodiment.

A first modification and a second modification of the sixth example embodiment in which only the multilayer structure of the piezoelectric substrate is different from that of the sixth example embodiment will be represented below. In the first modification and the second modification as well, the region on the piezoelectric substrate can efficiently be utilized and the energy of the acoustic wave can effectively be confined to the piezoelectric layer side as in the sixth example embodiment.

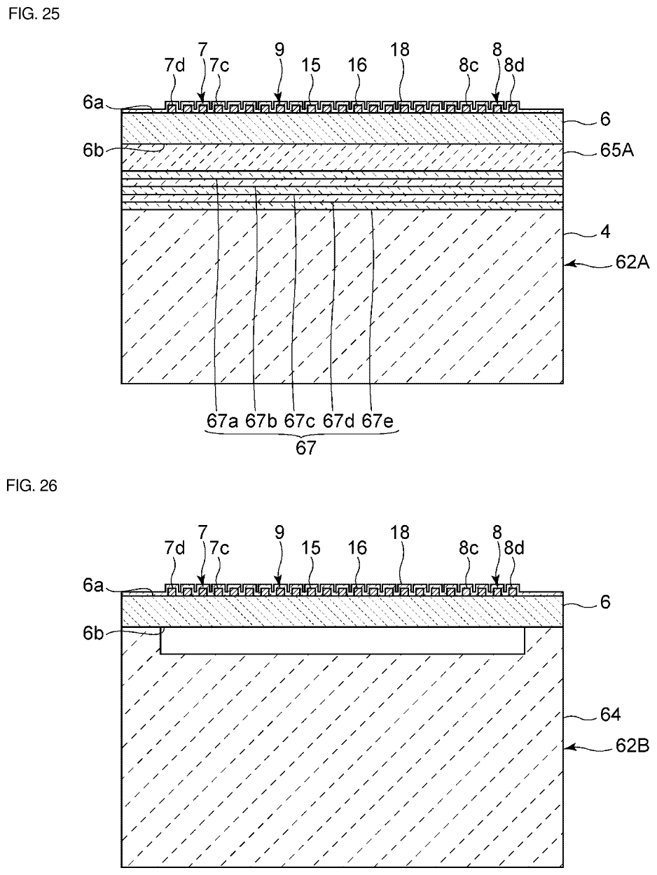

In the first modification shown in FIG. 25, a piezoelectric substrate 62A includes the support substrate 4, an acoustic reflection film 67, an intermediate layer 65A, and the piezoelectric layer 6. The acoustic reflection film 67 is provided on the support substrate 4. The intermediate layer 65A is provided on the acoustic reflection film 67. The piezoelectric layer 6 is provided on the intermediate layer 65A. The intermediate layer 65A is a low acoustic velocity film.

The acoustic reflection film 67 is a multilayer body including multiple acoustic impedance layers. Specifically, the acoustic reflection film 67 includes multiple low acoustic impedance layers and multiple high acoustic impedance layers. A high acoustic impedance layer is a layer that has relatively high acoustic impedance. More specifically, the multiple high acoustic impedance layers in the acoustic reflection film 67 are a high acoustic impedance layer 67a, a high acoustic impedance layer 67c, and a high acoustic impedance layer 67e. On the other hand, a low acoustic impedance layer is a layer that has relatively low acoustic impedance. More specifically, the multiple low acoustic impedance layers in the acoustic reflection film 67 are a low acoustic impedance layer 67b and a low acoustic impedance layer 67d. The low acoustic impedance layers and the high acoustic impedance layers are alternately stacked. Here, the high acoustic impedance layer 67a is the layer located closest to the piezoelectric layer 6 side in the acoustic reflection film 67.

The acoustic reflection film 67 includes the two low acoustic impedance layers and the three high acoustic impedance layers. Nonetheless, the acoustic reflection film 67 only needs to include at least one low acoustic impedance layer and one high acoustic impedance layer.

Silicon oxide, aluminum, or the like can be used as a material of the low acoustic impedance layers, for example. A metal such as platinum or tungsten or a dielectric material such as aluminum nitride or silicon nitride can be used as a material of the high acoustic impedance layers, for example. Note that the material of the intermediate layer 65A may be the same as the material of the low acoustic impedance layers.

In the second modification shown in FIG. 26, a piezoelectric substrate 62B includes a support substrate 64 and the piezoelectric layer 6. The piezoelectric layer 6 is directly provided on the support substrate 64. More specifically, the support substrate 64 includes a recessed portion. The piezoelectric layer 6 is provided on the support substrate 64 in such a way as to close the recessed portion. Thus, the piezoelectric substrate 62B has a hollow portion. The hollow portion overlaps at least a portion of the IDT electrode 9 in plan view.

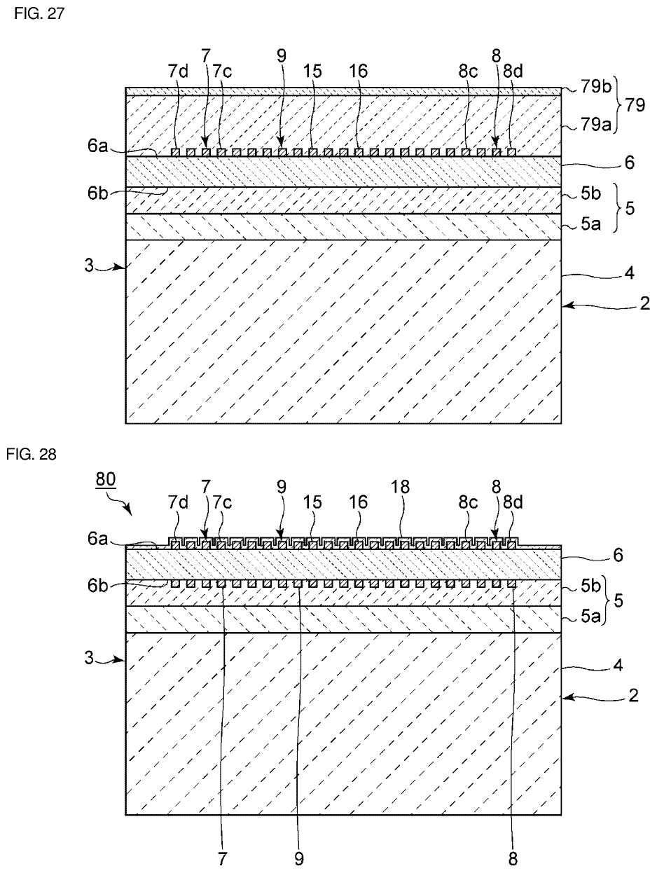

FIG. 27 is a schematic elevational cross-sectional view of an acoustic wave device according to a seventh example embodiment of the present invention.

The present example embodiment is different from the first example embodiment in that the IDT electrode 9 includes a protection film 79 instead of the dielectric film 18 shown in FIG. 2. The IDT electrode 9 is embedded in the protection film 79. Except for the aforementioned points, the acoustic wave device of the present example embodiment has the same configuration as the acoustic wave device 10 of the first example embodiment.

Specifically, the protection film 79 is provided on the piezoelectric layer 6 in such a way as to cover the IDT electrode 9. A thickness of the protection film 79 is larger than the thickness of the IDT electrode 9. The IDT electrode 9 is embedded in the protection film 79. Thus, the IDT electrode 9 is hardly damaged.

The protection film 79 includes a first protection layer 79a and a second protection layer 79b. The IDT electrode 9 is embedded in the first protection layer 79a. The second protection layer 79b is provided on the first protection layer 79a. Thus, multiple effects can be obtained from the protection film 79. Specifically, in the present example embodiment, silicon oxide is used as a material of the first protection layer 79a. Accordingly, it is possible to reduce an absolute value of a temperature coefficient of frequency (TCF) in the acoustic wave device. Thus, temperature characteristics of the acoustic wave device can be improved. Silicon nitride is used for the second protection layer 79b. Accordingly, moisture resistance of the acoustic wave device can be increased.

In addition, in the present example embodiment as well, the IDT electrode 9, the first reflector 7, and the second reflector 8 are provided in the same manner as in the first example embodiment. Accordingly, the region on the piezoelectric substrate 2 can efficiently be utilized.

Here, the materials of the first protection layer 79a and the second protection layer 79b are not limited to the aforementioned materials. The protection film 79 may include a single layer or may be a multilayer body including three or more layers.

FIG. 28 is a schematic elevational cross-sectional view of an acoustic wave device according to an eighth example embodiment.

The present example embodiment is different from the first example embodiment in that both of the first principal surface 6a and the second principal surface 6b of the piezoelectric layer 6 are provided with the IDT electrodes 9. Here, the IDT electrode 9 provided to the second principal surface 6b is embedded in the second layer 5b of the intermediate layer 5. Except for the aforementioned points, an acoustic wave device 80 has the same configuration as the acoustic wave device 10 of the first example embodiment.

The IDT electrode 9 provided to the first principal surface 6a of the piezoelectric layer 6 and the IDT electrode 9 provided to the second principal surface 6b thereof are opposed to each other with the piezoelectric layer 6 interposed therebetween. Likewise, the first reflector 7 provided to the first principal surface 6a of the piezoelectric layer 6 and the first reflector 7 provided to the second principal surface 6b thereof are opposed to each other with the piezoelectric layer 6 interposed therebetween. The second reflector 8 provided to the first principal surface 6a of the piezoelectric layer 6 and the second reflector 8 provided to the second principal surface 6b thereof are opposed to each other with the piezoelectric layer 6 interposed therebetween.

In the acoustic wave device 80, the IDT electrode 9, the first reflector 7, and the second reflector 8 are constituted on the first principal surface 6a in the same manner as in the first example embodiment. The same applies to the second principal surface 6b. Thus, the region on the first principal surface 6a and the region on the second principal surface 6b of the piezoelectric layer 6 in the piezoelectric substrate 2 can efficiently be used.

Here, the IDT electrodes 9 provided to the first principal surface 6a and the second principal surface 6b of the piezoelectric layer 6 may have design parameters that are different from each other, for example. The same applies to the first reflectors 7 and the second reflectors 8 provided to the first principal surface 6a and the second principal surface 6b.

First to third modifications of the eighth example embodiment in which at least only one of the configurations of the electrodes provided to the second principal surface of the piezoelectric layer and the multilayer structure of the piezoelectric substrate is different from that of the eighth example embodiment will be shown below. The first to third modifications can also suppress the out-of-band unnecessary wave as in the eighth example embodiment.

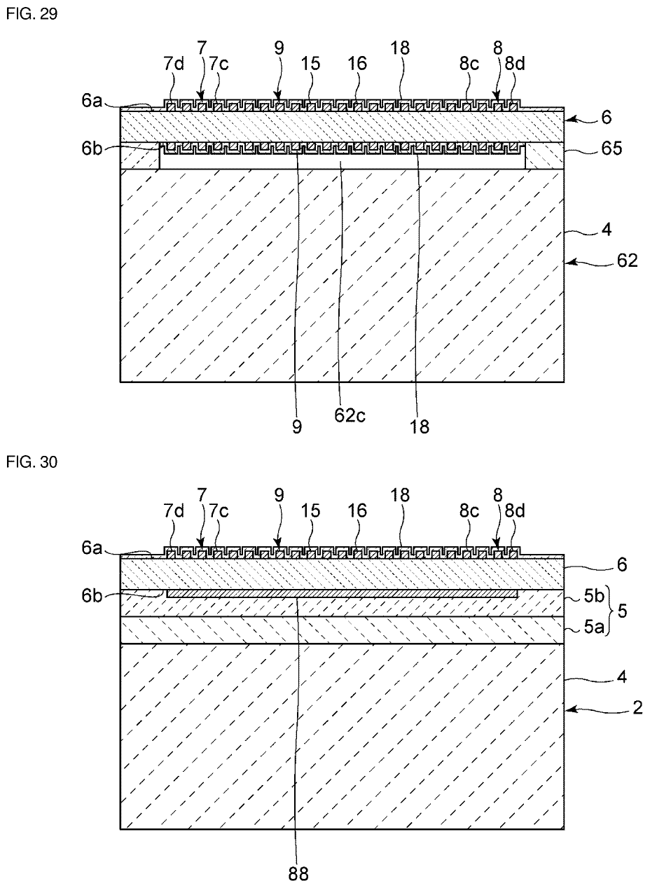

In the first modification shown in FIG. 29, the piezoelectric substrate 62 is provided in the same manner as in the sixth example embodiment. Specifically, the piezoelectric substrate 62 includes the support substrate 4, the intermediate layer 65, and the piezoelectric layer 6. The IDT electrode 9 provided to the second principal surface 6b of the piezoelectric layer 6 is located inside the hollow portion 62c. In the present modification, the dielectric film 18 is provided to the second principal surface 6b of the piezoelectric layer 6 in such a way as to cover the IDT electrode 9. The material of the dielectric film 18 may be the same material as the material of the intermediate layer 65 or a different material from the material of the intermediate layer 65. Nonetheless, the dielectric film 18 does not necessarily have to be provided.

In the second modification shown in FIG. 30, an electrode 88 in a plate shape is provided to the second principal surface 6b of the piezoelectric layer 6. The IDT electrode 9 and the electrode 88 are opposed to each other with the piezoelectric layer 6 interposed therebetween. The electrode 88 is embedded in the second layer 5b.

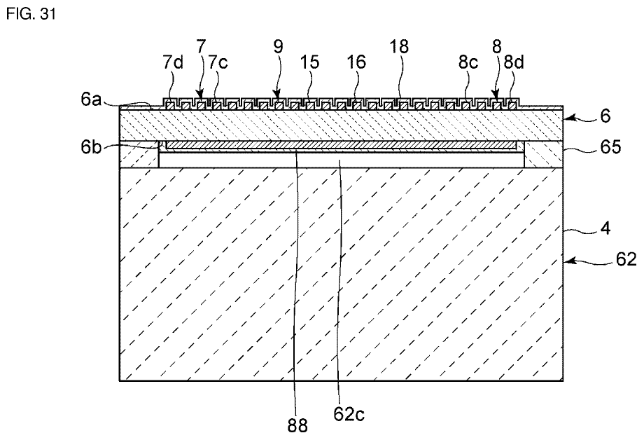

In the third modification shown in FIG. 31, the piezoelectric substrate 62 is provided in the same manner as in the first modification, and the electrode 88 configured in the same manner as in the second modification is provided to the second principal surface 6b of the piezoelectric layer 6. The electrode 88 is located inside the hollow portion 62c. The dielectric film 18 is provided to the second principal surface 6b in such a way as to cover the electrode 88. Nonetheless, the dielectric film 18 does not necessarily have to be provided.

The sixth to eighth example embodiments and the respective modifications thereof have shown the examples in which the IDT electrode 9, the first reflector 7, and the second reflector 8 have the same configurations as those of the first example embodiment. Note that the piezoelectric substrate of any of the sixth to eighth example embodiments and the respective modifications thereof can be adopted even in the case where the configurations of the IDT electrode and the respective reflectors apply the configurations of example embodiments of the present invention other than the first example embodiment. In the meantime, the piezoelectric substrate may be a substrate consisting of the piezoelectric layer.

An example of procedures to read the shapes of the electrode fingers of the IDT electrode and the reflector electrode fingers of the first reflector and the second reflector will be described below.

First, an image including electrode fingers or reflector electrode fingers is obtained with a microscope and the like. For example, a scanning electron microscope (SEM), an optical microscope, or a laser scanning microscope may be used in this instance.

Next, processing is conducted in such a way as to render an end portion of each electrode finger discernible by adjusting contrast and the like of the image. Next, the end portion of the electrode finger is detected and coordinate values of the end portion are extracted. Next, an outline of the end portion of the electrode finger thus extracted is complemented with a curve subjected to polynomial approximation in an appropriate region size.

Next, a gravity center is obtained from curves on two edges of the electrode finger. The gravity center stated herein is assumed to be a linear gravity center. Specifically, a line obtained by linking center points of straight lines each connecting between any points adjacent to the curves of the two edges will be defined as the gravity center.

Next, normal directions at the respective coordinate points are calculated from expressions of the curves. Next, a width of the electrode finger, an electrode finger pitch, and a duty ratio are calculated based on the normal directions. Here, a dimension along the normal direction of the electrode finger will be defined as the width of the electrode finger. A center-to-center distance in the normal direction between the electrode fingers located adjacent to each other will be defined as the electrode finger pitch. A value obtained by dividing the width of the electrode finger by the electrode finger pitch will be defined as the duty ratio.

A curvature represents a degree of curvature of a curved line or a curved surface. A radius at any point on the curved line in a case of being locally approximated to an arc may be calculated and an inverse number of the radius may be expressed as the curvature. That is to say, when the calculated radius is r, the curvature is expressed by 1/r.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer;
an IDT electrode on the piezoelectric layer and including a pair of busbars and a plurality of electrode fingers; and
a first reflector and a second reflector positioned on the piezoelectric layer to be opposed to each other with the IDT electrode interposed therebetween, each of the first and second reflectors including a pair of reflector busbars and a plurality of reflector electrode fingers; wherein
shapes in plan view of the plurality of electrode fingers of the IDT electrode are curved shapes;
a direction of excitation of an acoustic wave at any portion of any specific electrode finger out of the plurality of electrode fingers is any of first to third directions;
the first direction is a direction perpendicular to a direction of extension of the specific electrode finger;
the second direction is a direction in which a distance between the specific electrode finger and another one of the electrode fingers located adjacent to the specific electrode finger is shortest; and
the third direction is a direction of an electric field vector generated between the specific electrode finger and the another one of the electrode fingers located adjacent to the specific electrode finger;
in the first reflector, the pair of reflector busbars are a first reflector busbar and a second reflector busbar opposed to each other, and shapes in plan view of the plurality of reflector electrode fingers in each of the first reflector and the second reflector are curved shapes;
the plurality of reflector electrode fingers in the first reflector include one or more first reflector electrode fingers including two end portions directly connected to the first reflector busbar and the second reflector busbar, and one or more second reflector electrode fingers including one end portion not directly connected to the first reflector busbar, the first reflector electrode fingers being located closer to an IDT electrode side than the second reflector electrode fingers;
when viewed from a direction in which the first reflector busbar and the second reflector busbar are opposed to each other, all of the second reflector electrode fingers overlap at least one of the first reflector busbar and the second reflector busbar; and
in at least a partial region of the first reflector, a direction of propagation of the acoustic wave is a direction toward a second reflector busbar side, and a number of the reflector electrode fingers increases in the partial region toward a side of the second reflector busbar.

2. The acoustic wave device according to claim 1, wherein the one end portion of each of the second reflector electrode fingers is not connected to an electrode, and another end portion of each of the second reflector electrode fingers is directly connected to the second reflector busbar.

3. The acoustic wave device according to claim 1, wherein
the first reflector further includes an end portion connection electrode connected to the first reflector busbar and the second reflector busbar; and
the one end portion of at least one of the second reflector electrode fingers is indirectly connected to the first reflector busbar via the end portion connection electrode, and another end portion of at least one of the second reflector electrode fingers is directly connected to the second reflector busbar.

4. The acoustic wave device according to claim 1, wherein
the first reflector further includes an end portion connection electrode connected to the first reflector busbar and the second reflector busbar;
the one end portion of at least one of the second reflector electrode fingers is indirectly connected to the first reflector busbar via the end portion connection electrode, and another end portion of at least one of the second reflector electrode fingers is indirectly connected to the second reflector busbar via the end portion connection electrode; and
in the partial region of the first reflector, the direction of propagation of the acoustic wave is the direction toward the second reflector busbar side and the number of the reflector electrode fingers increases in the partial region toward the second reflector busbar side, and in another partial region of the first reflector, the direction of propagation of the acoustic wave is a direction toward the first reflector busbar side and the number of the reflector electrode fingers increases in the another partial region toward the first reflector busbar side.

5. The acoustic wave device according to claim 1, wherein, when viewed from the direction in which the first reflector busbar and the second reflector busbar are opposed to each other, at least a portion of each of the second reflector electrode fingers overlaps both of the first reflector busbar and the second reflector busbar.

6. The acoustic wave device according to claim 1, wherein
in the second reflector, the pair of reflector busbars are a third reflector busbar and a fourth reflector busbar opposed to each other;
the plurality of reflector electrode fingers in the second reflector include one or more third reflector electrode fingers including two end portions directly connected to the third reflector busbar and the fourth reflector busbar, and one or more fourth reflector electrode fingers including one end portion not directly connected to the fourth reflector busbar, the third reflector electrode fingers being located closer to the IDT electrode side than the fourth reflector electrode fingers;
when viewed from a direction in which the third reflector busbar and the fourth reflector busbar are opposed to each other, all of the fourth reflector electrode fingers overlap at least one of the third reflector busbar and the fourth reflector busbar; and
in at least a partial region of the second reflector, the direction of propagation of the acoustic wave is a direction toward the third reflector busbar side, and the number of the reflector electrode fingers increases in the partial region of the second reflector toward the third reflector busbar side.

7. The acoustic wave device according to claim 6, wherein, when viewed from the direction in which the third reflector busbar and the fourth reflector busbar are opposed to each other, all of the fourth reflector electrode fingers overlap both of the third reflector busbar and the fourth reflector busbar.

8. The acoustic wave device according to claim 1, wherein the number of the plurality of reflector electrode fingers in the first reflector and the number of the plurality of reflector electrode fingers in the second reflector are different from each other.

9. The acoustic wave device according to claim 1, wherein at least one of an electrode finger pitch and a duty ratio is constant at portions of the IDT electrode where the direction of excitation is the same.

10. The acoustic wave device according to claim 1, wherein
the plurality of electrode fingers in the IDT electrode include a plurality of first electrode fingers and a plurality of second electrode fingers interdigitated with one another;
an imaginary line connecting tip ends at tip end portions of the plurality of second electrode fingers is defined as a first envelope, an imaginary line connecting tip ends at tip end portions of the plurality of first electrode fingers is defined as a second envelope, and a region in the IDT electrode located between the first envelope and the second envelope is an intersecting region; and
in the intersecting region, resonant frequencies or anti-resonant frequencies in a main mode substantially coincide with one another.

11. The acoustic wave device according to claim 1, wherein
the pair of busbars in the IDT electrode are a first busbar and a second busbar opposed to each other, the plurality of electrode fingers are a plurality of first electrode fingers and a plurality of second electrode fingers, one end portion of each of the plurality of first electrode fingers is connected to the first busbar, one end portion of each of the plurality of second electrode fingers is connected to the second busbar, and the plurality of first electrode fingers and the plurality of second electrode fingers are interdigitated with one another;
the IDT electrode further includes a plurality of offset electrodes, each of which includes one end portion connected to at least the first busbar out of the pair of busbars; and
other end portions of the plurality of offset electrodes, each of which has the one end portion connected to the first busbar, are opposed to the plurality of second electrode fingers with a gap provided therebetween.

12. The acoustic wave device according to claim 1, wherein
the pair of busbars in the IDT electrode are a first busbar and a second busbar opposed to each other;
at least the first busbar out of the pair of busbars includes an inner busbar portion and an outer busbar portion opposed to each other, and a plurality of connecting portions connecting the inner busbar portion to the outer busbar portion;
in the first busbar, the inner busbar portion is located on the second busbar side; and
the first busbar is provided with a plurality of apertures surrounded by the inner busbar portion, the outer busbar portion, and the plurality of connecting portions.

13. The acoustic wave device according to claim 1, wherein
the plurality of electrode fingers in the IDT electrode are a plurality of first electrode fingers and a plurality of second electrode fingers interdigitated with one another;
an imaginary line connecting tip ends at tip end portions of the plurality of second electrode fingers is defined as a first envelope, an imaginary line connecting tip ends at tip end portions of the plurality of first electrode fingers is defined as a second envelope, and a region in the IDT electrode located between the first envelope and the second envelope is an intersecting region;
the intersecting region includes a first edge region including the first envelope, a second edge region including the second envelope, and a central region interposed between the first edge region and the second edge region; and
in at least one of the first edge region and the second edge region, at least one of the electrode fingers includes a broadened portion having a width larger than a width of the electrode finger in the central region.

14. The acoustic wave device according to claim 1, wherein
the plurality of electrode fingers in the IDT electrode are a plurality of first electrode fingers and a plurality of second electrode fingers interdigitated with one another;
an imaginary line connecting tip ends at tip end portions of the plurality of second electrode fingers is defined as a first envelope, an imaginary line connecting tip ends at tip end portions of the plurality of first electrode fingers is defined as a second envelope, and a region in the IDT electrode located between the first envelope and the second envelope is an intersecting region; and
the intersecting region includes a first edge region including the first envelope, a second edge region including the second envelope, and a central region interposed between the first edge region and the second edge region;
the acoustic wave device further comprising a mass addition film provided in at least one of the first edge region and the second edge region to overlap at least one of the plurality of first electrode fingers and the plurality of second electrode fingers in plan view.

15. The acoustic wave device according to claim 1, wherein
the plurality of electrode fingers in the IDT electrode are a plurality of first electrode fingers and a plurality of second electrode fingers interdigitated with one another;
an imaginary line connecting tip ends at tip end portions of the plurality of second electrode fingers is defined as a first envelope, an imaginary line connecting tip ends at tip end portions of the plurality of first electrode fingers is defined as a second envelope, and a region in the IDT electrode located between the first envelope and the second envelope is an intersecting region;
the intersecting region includes a first edge region including the first envelope, a second edge region including the second envelope, and a central region interposed between the first edge region and the second edge region; and
in at least one of the first edge region and the second edge region, at least one of the electrode fingers has a thickness larger than a thickness of the electrode finger in the central region.

16. The acoustic wave device according to claim 1, wherein
the piezoelectric substrate includes a support substrate; and
the piezoelectric layer is provided on the support substrate.

17. The acoustic wave device according to claim 16, wherein the piezoelectric substrate includes an intermediate layer between the support substrate and the piezoelectric layer.

18. The acoustic wave device according to claim 16, wherein the piezoelectric substrate includes a hollow portion, and a portion of the support substrate and a portion of the piezoelectric layer are opposed to each other with the hollow portion interposed therebetween.

19. The acoustic wave device according to claim 1, wherein the piezoelectric substrate consists of the piezoelectric layer.
